(19) United States
(12) Patent Application Publication
(10) Pub. No.: US 2025/0006550 A1
(43) Pub. Date: Jan. 2, 2025

(54) METHOD AND SYSTEM OF ARRANGING PATTERNS OF SEMICONDUCTOR DEVICE

(71) Applicant: TAIWAN SEMICONDUCTOR MANUFACTURING COMPANY LTD., HSINCHU (TW)

(72) Inventor: KAZUYUKI TATEISHI, HSINCHU (TW)

(21) Appl. No.: 18/346,267

(22) Filed: Jul. 2, 2023

(51) Int. Cl. H01L 21/768; G03F 1/76; H01L 21/027

(52) U.S. Cl. CPC H01L 21/76816; G03F 1/76; H01L 21/0274

(57) ABSTRACT

A method and system of arranging patterns of a semiconductor device are provided. The method includes placing a first pin and a second pin. The method also includes generating a plurality of first conductive patterns. The method further includes selecting a first set of the plurality of first conductive patterns. In addition, the method includes placing a plurality of interconnection patterns to connect the first pin, the first set of the plurality of first conductive patterns, and the second pin. The method also includes placing cut patterns overlapping the first set of the plurality of first conductive patterns to form an isolated pattern including the first pin, the first set of the plurality of first conductive patterns, and the second pin.

### BACKGROUND

Industry requirements for decreased size in integrated circuits (ICs) have resulted in smaller devices which consume less power yet provide more functionality at higher speeds. The miniaturization process has also resulted in stricter design and manufacturing specifications as well as reliability challenges. Various electronic design automation (EDA) tools generate, optimize, and verify standard cell layout designs for integrated circuits while ensuring that the standard cell layout design and manufacturing specifications are met.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is a flowchart of a method for manufacturing a semiconductor device according to various aspects of the present disclosure.

FIG. 2A, FIG. 2B, FIG. 2C, FIG. 2D, FIG. 2E, FIG. 2F and FIG. 2G illustrate various stages in the manufacture of a layout for a semiconductor device, in accordance with some embodiments of the present disclosure.

FIG. 3A, FIG. 3B, FIG. 3C, FIG. 3D, FIG. 3E, FIG. 3F, FIG. 3G and FIG. 3H illustrate various stages in the manufacture of a layout for a semiconductor device, in accordance with some embodiments of the present disclosure.

FIG. 4A and FIG. 4B illustrate various stages in the manufacture of a layout for a semiconductor device, in accordance with some embodiments of the present disclosure.

FIG. 5A is a flowchart of a method for manufacturing a layout of a semiconductor device according to various aspects of the present disclosure.

FIG. 5B is a flowchart of a method for manufacturing a layout of a semiconductor device according to various aspects of the present disclosure.

FIG. 5C is a flowchart of a method for manufacturing a layout of a semiconductor device according to various aspects of the present disclosure.

FIG. 5D is a flowchart of a method for manufacturing a layout of a semiconductor device according to various aspects of the present disclosure.

FIG. 5E is a flowchart of a method for manufacturing a layout of a semiconductor device according to various aspects of the present disclosure.

FIG. 5F is a flowchart of a method for manufacturing a layout of a semiconductor device according to various aspects of the present disclosure.

FIG. 5G is a flowchart of a method for manufacturing a layout of a semiconductor device according to various aspects of the present disclosure.

FIG. 6 is a flowchart of a method for manufacturing a layout of a semiconductor device according to various aspects of the present disclosure.

FIG. 7 is a block diagram of a system of designing a semiconductor device, in accordance with some embodiments.

FIG. 8 is a block diagram of a semiconductor device manufacturing system, and a semiconductor device flow associated therewith, in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below.” “lower.” “above,” “over,” “upper.” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first.” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially.” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially.” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

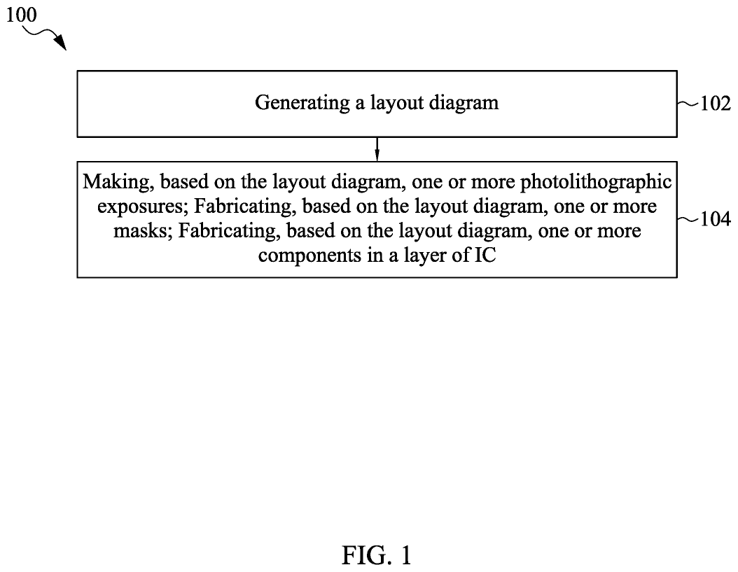

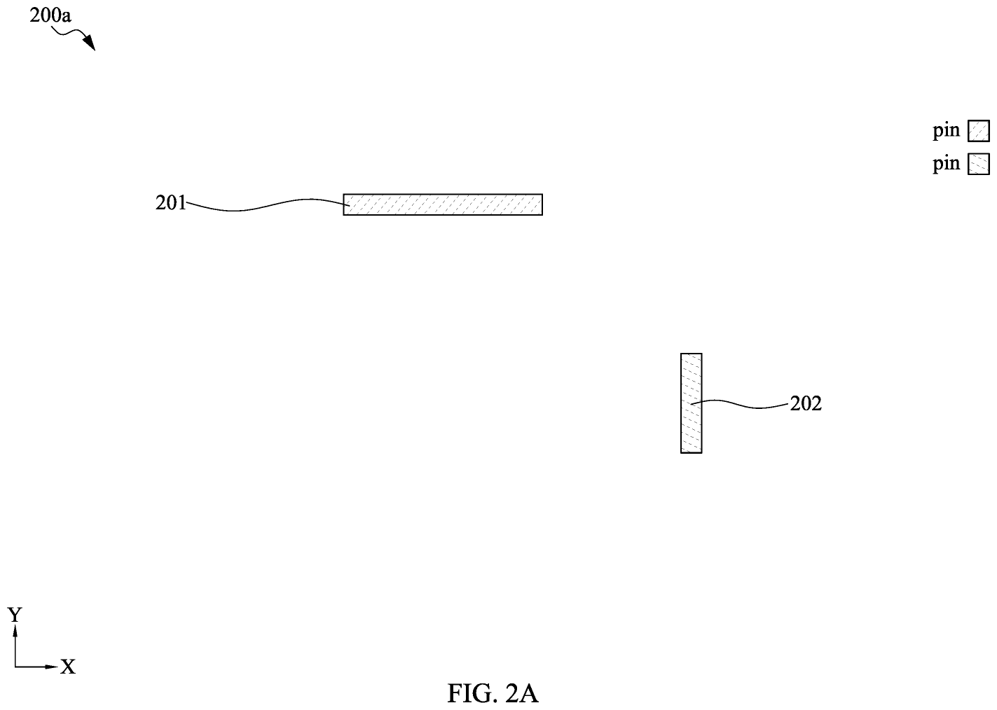

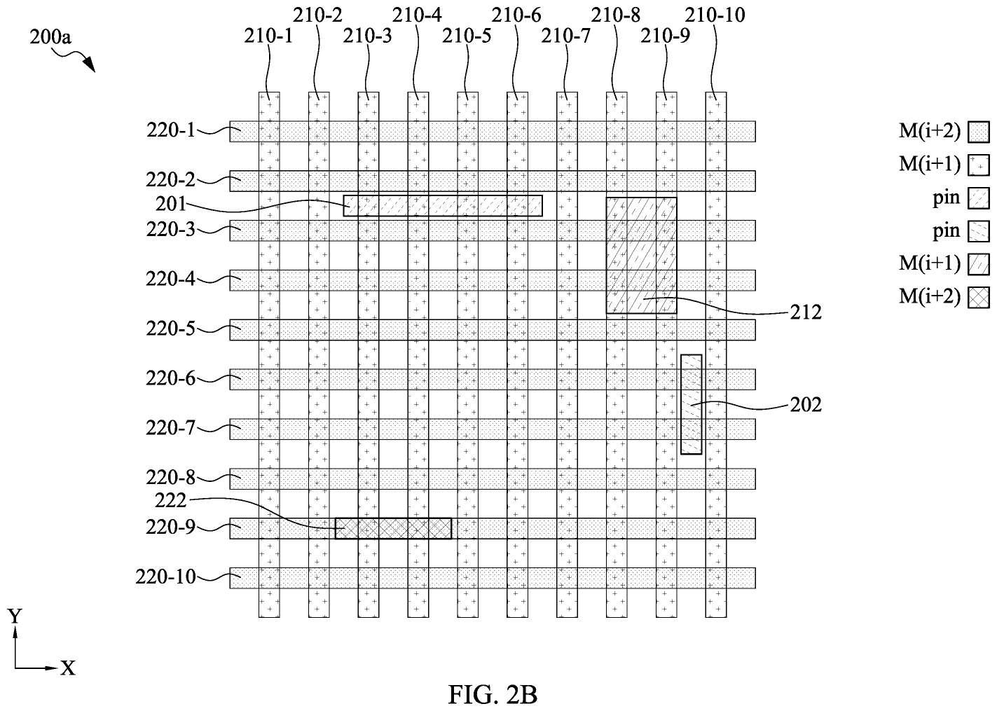

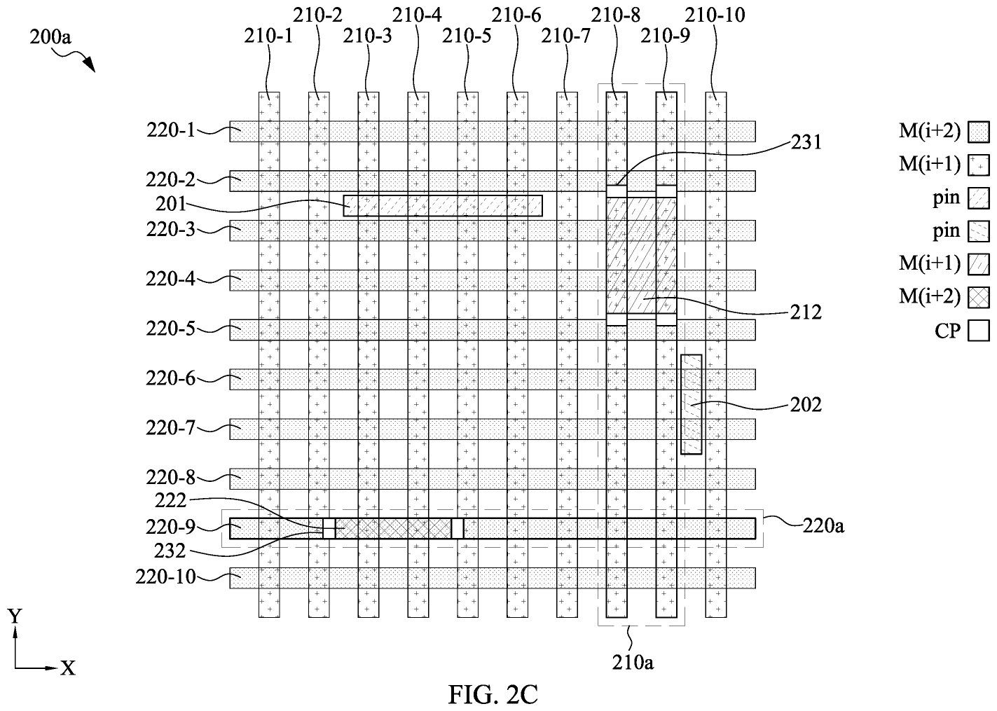

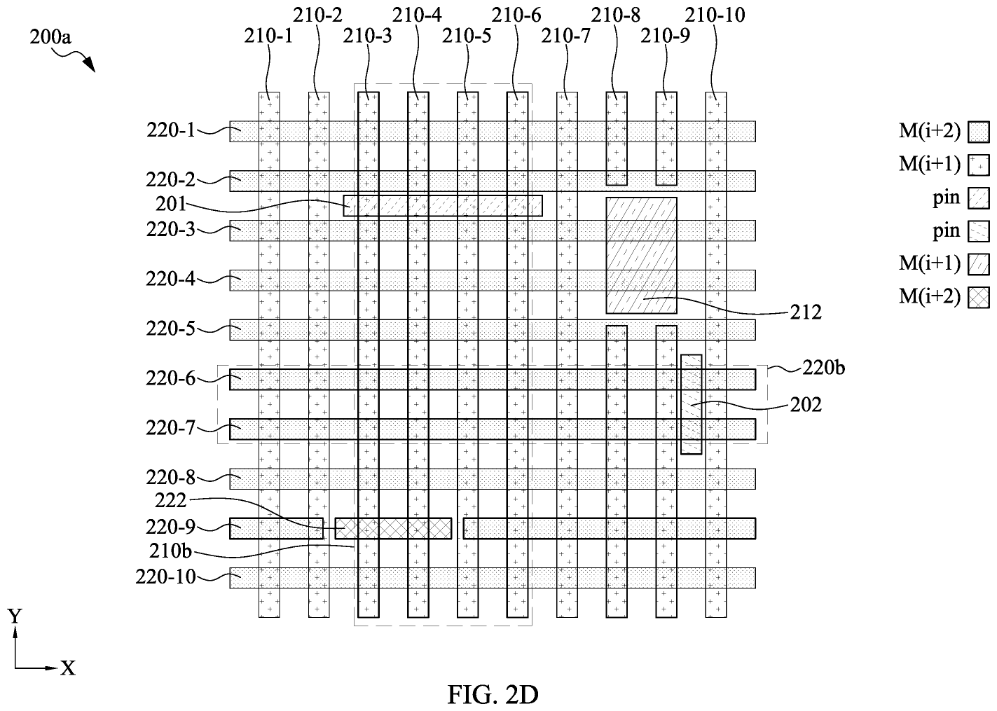

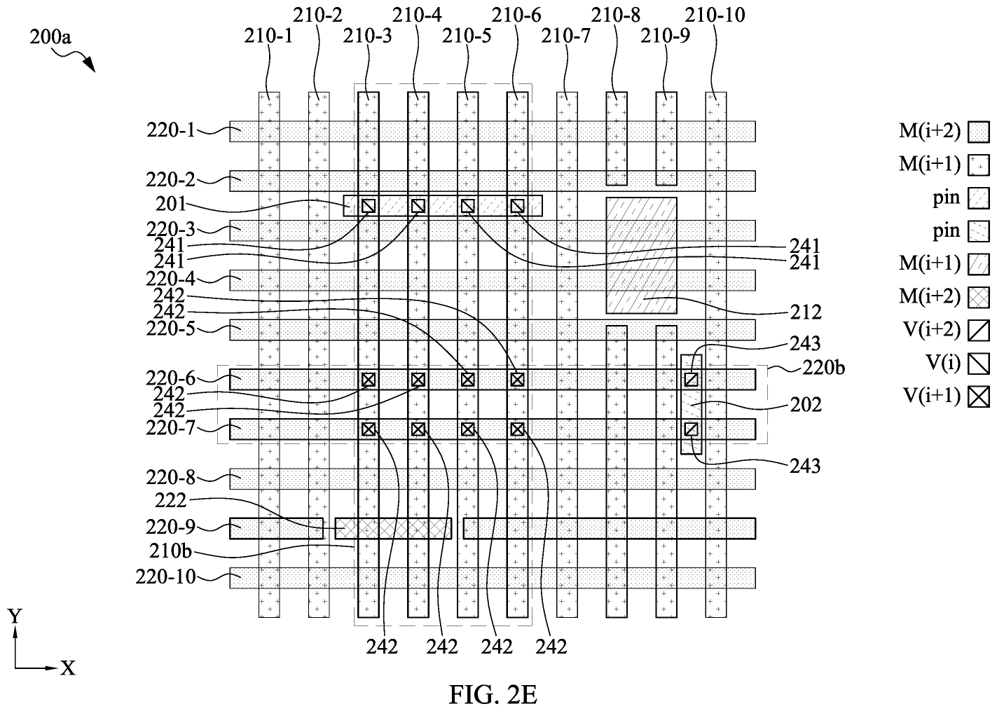

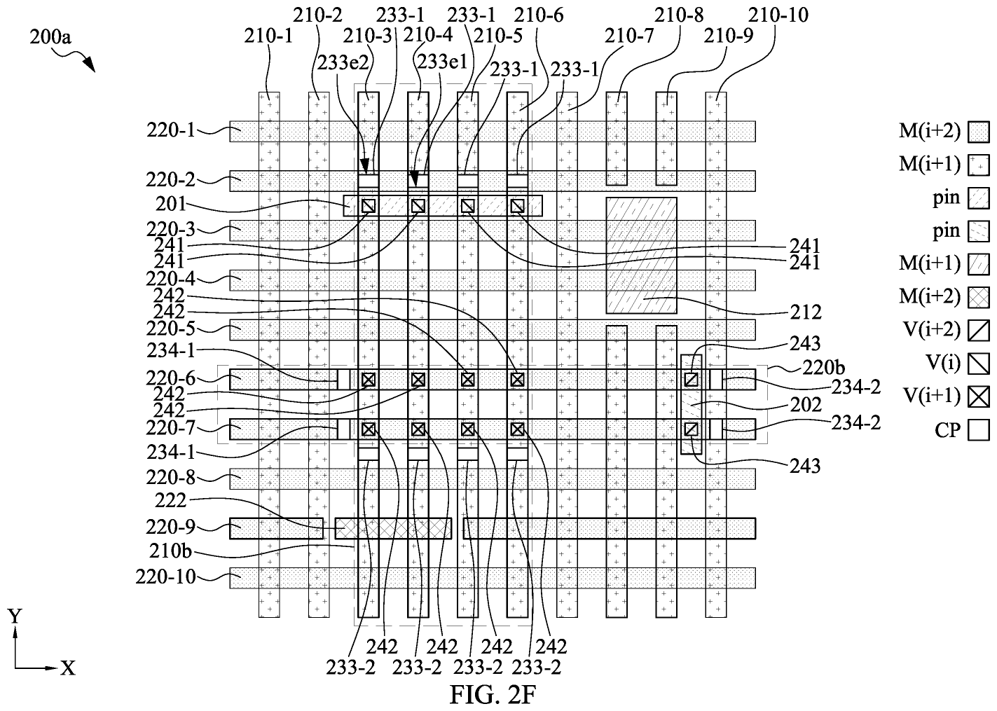

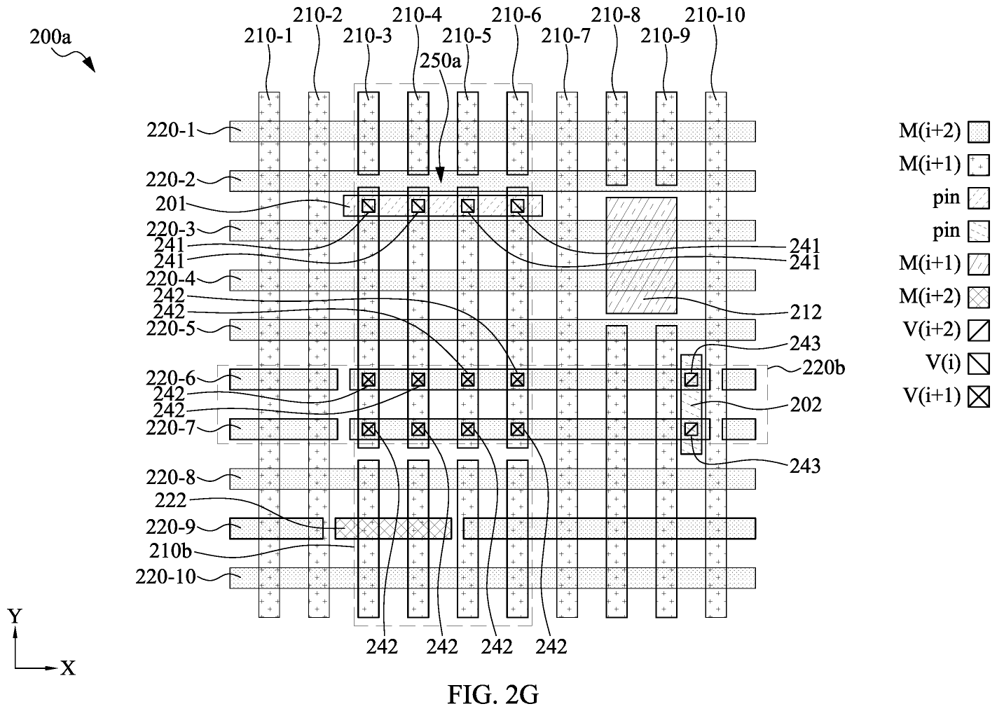

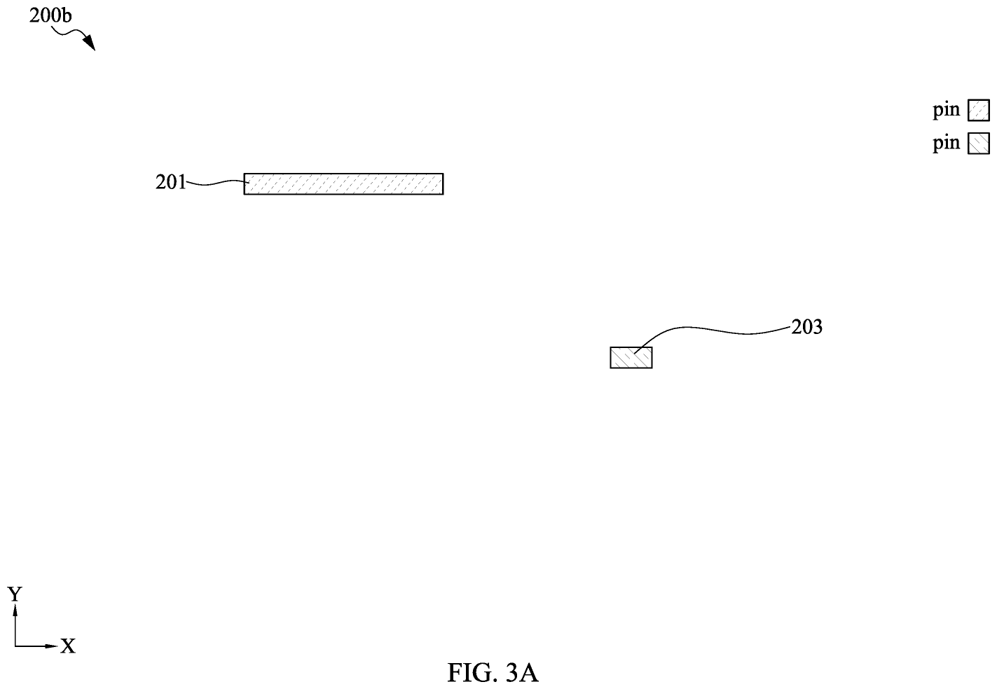

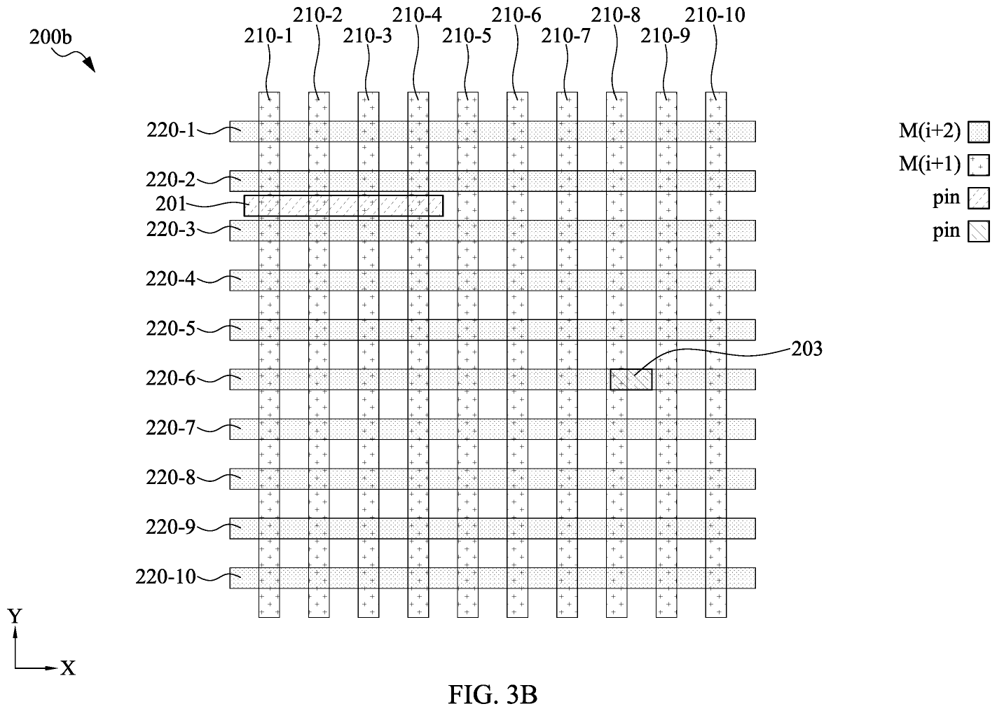

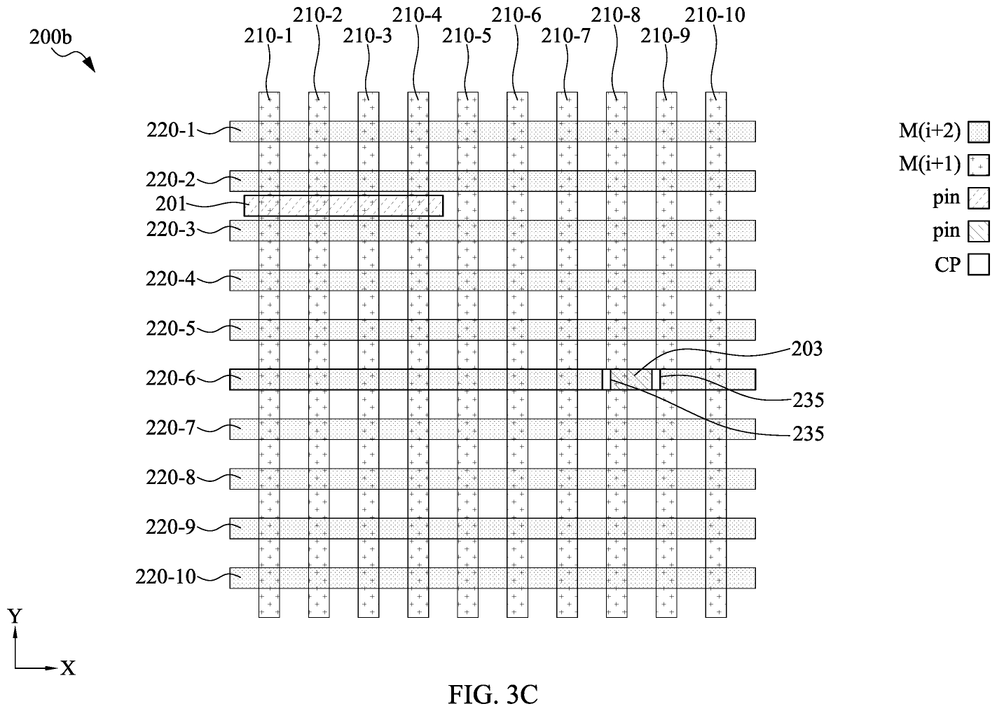

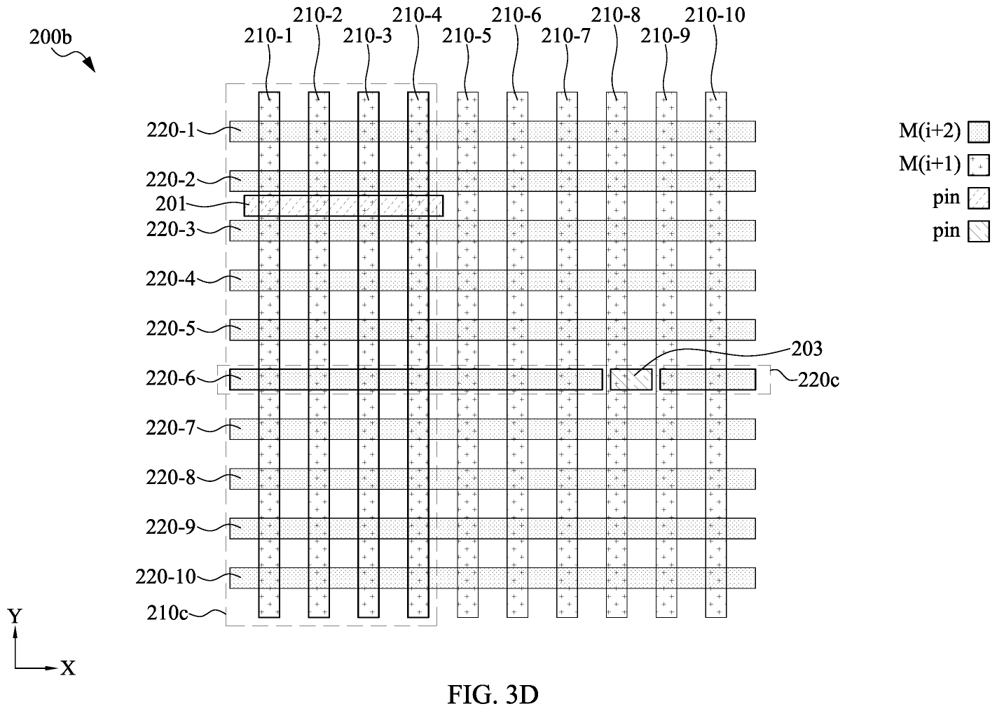

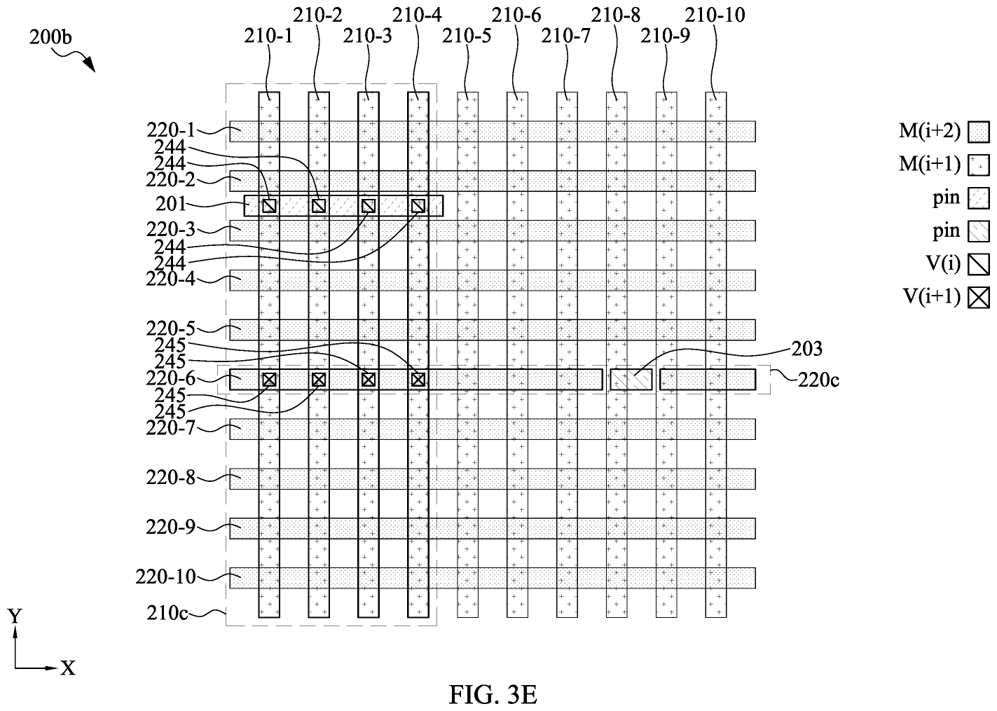

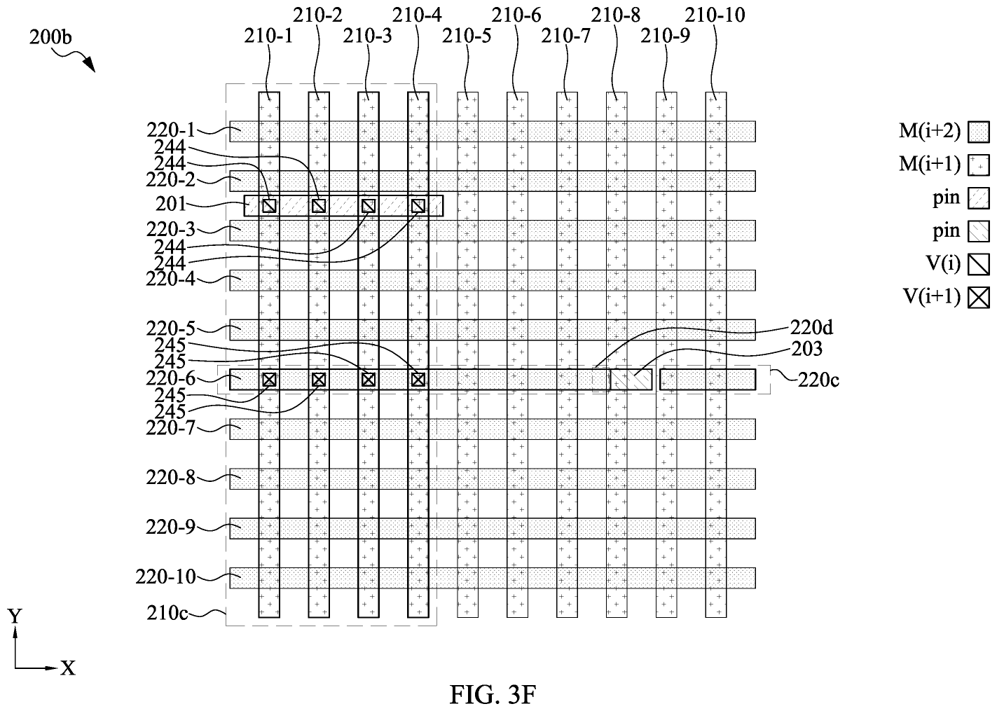

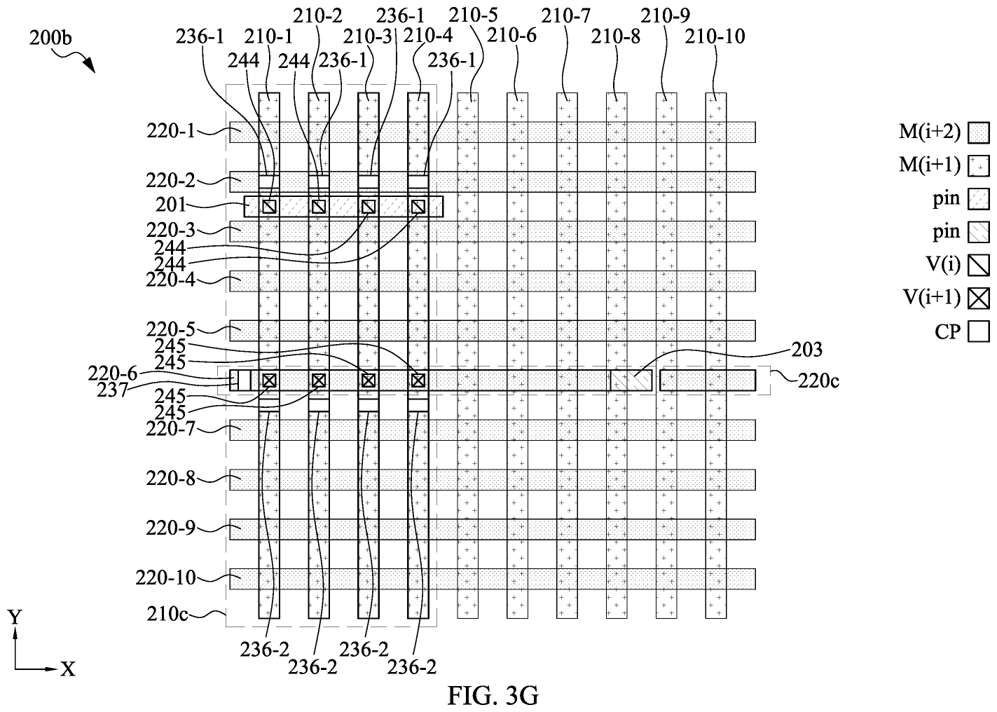

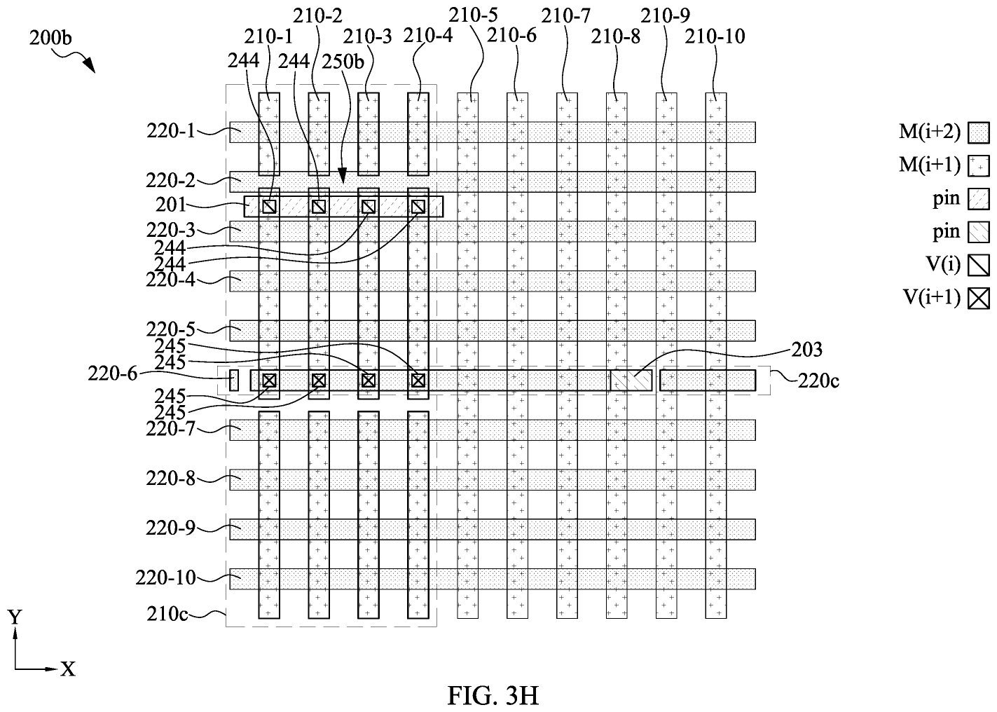

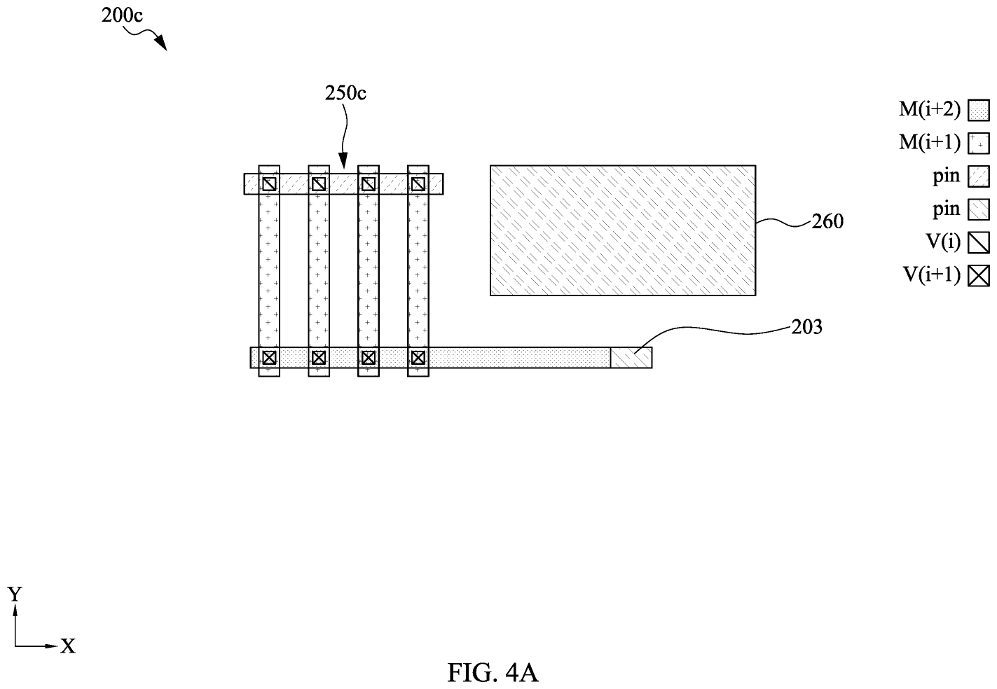

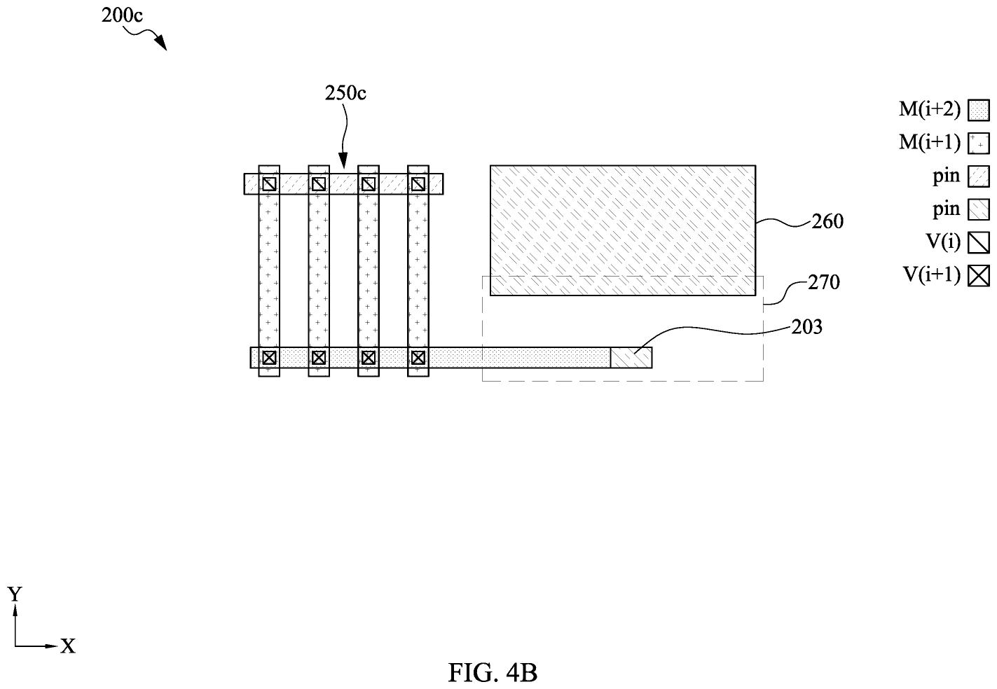

FIG. 1 illustrates a method 100 of manufacturing a semiconductor device, in accordance with some embodiments. FIG. 2A to FIG. 2G, FIG. 3A to FIG. 3H, FIG. 4A and FIG. 4B illustrate methods of manufacturing a layout of a semiconductor device, in accordance with some embodiments.

In some embodiments, method 100 includes operations 102 and 104. The method begins with operation 102 in which a layout diagram is generated. The layout diagram is discussed in more detail as follows with respect to FIG. 2A to FIG. 2G, FIG. 3A to FIG. 3H, FIG. 4A and FIG. 4B. More specifically, FIG. 2A to FIG. 2G and FIG. 3A to FIG. 3H illustrate how to produce an isolated pattern that can function as a dummy pattern of the semiconductor device. In this embodiment, the dummy pattern is produced before the functional circuits, and can be referred to as a first-dummy-fill technique. FIG. 4A to FIG. 4B illustrate a procedure to connect an isolated pattern and a circuit pattern.

The method 100 continues with operation 104: based on the layout diagram, in which at least one of (A) one or more photolithographic exposures are made or (B) one or more semiconductor masks are fabricated or (C) one or more components in a layer of a semiconductor device are fabricated.

FIG. 2A, FIG. 2B, FIG. 2C, FIG. 2D, FIG. 2E, FIG. 2F, and FIG. 2G illustrate various stages in the manufacture of a layout 200a for a semiconductor device, in accordance with some embodiments of the present disclosure.

Referring to FIG. 2A, a pin 201 and a pin 202 are placed. In some embodiments, each of the pin 201 and/or pin 202 is a terminal of a layout. In some embodiments, the pin 201 corresponds to the M(i) of a metallization layer of the semiconductor device, where i is an integer and i≥0. In some embodiments, the pin 201 corresponds to the M0 of the metallization layer of the semiconductor device. In this disclosure, the term “M0” or “M0 of the metallization layer” can refer to the lowest metallization layer (or a metallization layer located at the lowest level) of a semiconductor device configured to electrically connect the gate structure (or source/drain feature) to upper metallization layers, such as M1, M2, M3, and so on. In some embodiments, the pin 202 corresponds to the M(i+m) of a metallization layer of the semiconductor device, where m is an integer and m≥2. In some embodiments, m is equal to 3. For example, the pin 202 corresponds to the M3 of the metallization layer of the semiconductor device.

Referring to FIG. 2B, conductive patterns 210-1, 210-2, 210-3, 210-4, 210-5, 210-6, 210-7, 210-8, 210-9, and 210-10 are generated. In some embodiments, each of the conductive patterns 210-1 to 210-10 corresponds to the M(i+1) of a metallization layer of the semiconductor device. For example, each of the conductive patterns 210-1 to 210-10 corresponds to the M1 of the metallization layer of the semiconductor device. Each of the conductive patterns 210-1 to 210-10 extends along the Y-axis and is arranged along the X-axis. Conductive patterns 220-1, 220-2, 220-3, 220-4, 220-5, 220-6, 220-7, 220-8, 220-9, and 220-10 are generated. In some embodiments, each of the conductive patterns 220-1 to 220-10 corresponds to the M(i+2) of a metallization layer of the semiconductor device. For example, each of the conductive patterns 220-1 to 220-10 corresponds to the M2 of the metallization layer of the semiconductor device. Each of the conductive patterns 220-1 to 220-10 extends along the X-axis and is arranged along the Y-axis. In some embodiments, a predetermined pattern 212 is placed. The predetermined pattern 212 corresponds to a region and/or pattern of the semiconductor device that is predetermined to form traces, such as routed traces to be electrically connected to a circuit, or predetermined to be a region which is free of traces. The predetermined pattern 212 is located at a level which is the same as that of the M(i+1), such as the M1, of a metallization layer of the semiconductor device and overlaps at least one of the conductive patterns 210-1 to 210-10. For example, the predetermined pattern 212 overlaps the conductive patterns 210-8 and 210-9. In some embodiments, a predetermined pattern 222 is placed. The predetermined pattern 222 corresponds to a region and/or pattern of the semiconductor device that is predetermined to form traces, such as routed traces to be electrically connected to a circuit, or predetermined to be a region which is free of traces. The predetermined pattern 222 is located at a level which is the same as that of the M(i+2), such as the M2, of a metallization layer of the semiconductor device and overlaps at least one of the conductive patterns 220-1 to 220-10. For example, the predetermined pattern 222 overlaps the conductive pattern 220-9.

Referring to FIG. 2C, a set 210a of the conductive patterns 210-1 to 210-10 is selected. In this disclosure, the term “a set” may include any number equal to or greater than 1. In some embodiments, the set 210a of the conductive patterns 210-1 to 210-10 overlaps the predetermined pattern 212. For example, the conductive patterns 210-8 and 210-9 are selected. Next, a plurality of cut patterns 231 are placed. Each of the cut patterns 231 is configured to define a region where a metallization layer is undesired or a region of a metallization layer to be cut so that the predetermined pattern 212 can be separated from the conductive patterns 210-1 to 210-10. The cut patterns 231 are located at a level which is the same as that of the M(i+1), such as the M1, of a metallization layer of the semiconductor device and overlap the set 210a of the conductive patterns 210-1 to 210-10. For example, the cut patterns 231 overlap the conductive patterns 210-8 and 210-9. A set 220a of the conductive patterns 220-1 to 220-10 is selected. In some embodiments, the set 220a of the conductive patterns 220-1 to 220-10 overlaps the predetermined pattern 222. For example, the conductive pattern 220-9 is selected. Next, a plurality of cut patterns 232 are placed. Each of the cut patterns 232 is configured to define a region where a metallization layer is undesired or a region of a metallization layer to be cut so that the predetermined pattern 222 can be separated from the conductive patterns 220-1 to 220-10. The cut patterns 232 are located at a level which is the same as that of the M(i+2), such as the M2, of a metallization layer of the semiconductor device and overlap the set 220a of the conductive patterns 220-1 to 220-10. For example, the cut patterns 232 overlap the conductive patterns 220-9. In this disclosure, the cut patterns can also be referred to as “CP” in a layout diagram.

Referring to FIG. 2D, the conductive patterns 210-8 and 210-9 are cut based on the cut patterns 231, and the predetermined pattern 212 is separated from the conductive patterns 210-1 to 210-10. The conductive patterns 220-9 are cut based on the cut patterns 232, and the predetermined pattern 222 is separated from the conductive patterns 220-1 to 220-10. In some embodiments, a set 210b of the conductive patterns 210-1 to 210-10 is selected. In some embodiments, the set 210b is configured to determine a metallization layer(s) which is electrically connected to the pin 201 and on which the interconnection pattern(s) is placed. In some embodiments, the set 210b of the conductive patterns 210-1 to 210-10 overlaps the pin 201. For example, the conductive patterns 210-3 to 210-6 are selected. In some embodiments, a set 220b of the conductive patterns 220-1 to 220-10 is selected. In some embodiments, the set 220b is configured to determine a metallization layer(s) which is electrically connected to the pin 202 and on which the interconnection pattern(s) is placed. In some embodiments, the set 220b of the conductive patterns 220-1 to 220-10 overlaps the pin 202. For example, the conductive patterns 220-6 and 220-7 are selected.

Referring to FIG. 2E, a plurality of interconnection patterns 241 are placed. Each of the interconnection patterns 241 overlaps the set 210b of the conductive patterns 210-1 to 210-10 and the pin 201. For example, each of the interconnection patterns 241 overlaps the conductive patterns 210-3 (or 210-4, or 210-5, or 210-6) and the pin 201. Each of the interconnection patterns 241 corresponds to V(i) of a via of the semiconductor device, which is located between the M(i) and M(i+1) of the metallization layers of the semiconductor device. For example, each of the interconnection patterns 241 corresponds to the V0 of the via which connects the M0 and M1 of the metallization layers of the semiconductor device. A plurality of interconnection patterns 242 are placed. Each of the interconnection patterns 242 overlaps the set 210b of the conductive patterns 210-1 to 210-10 and the set 220b of the conductive patterns 220-1 to 220-10. For example, each of the interconnection patterns 242 overlaps the conductive pattern 210-3 (or 210-4, or 210-5, or 210-6) and the conductive pattern 220-6 (or 220-7). Each of the interconnection patterns 242 corresponds to V(i+1) of a via of the semiconductor device, which is located between the M(i+1) and M(i+2) of the metallization layers of the semiconductor device. For example, each of the interconnection patterns 242 corresponds to the V1 of the via that connects the M1 and M2 of the metallization layers of the semiconductor device. A plurality of interconnection patterns 243 are placed. Each of the interconnection patterns 243 overlaps the set 220b of the conductive patterns 220-1 to 220-10 and the pin 202. For example, each of the interconnection patterns 243 overlaps the conductive pattern 220-6 (or 220-7) and the pin 202. Each of the interconnection patterns 243 corresponds to V(i+2) of a via, which is located between the M(i+2) and M(i+3) of the metallization layers of the semiconductor device. For example, each of the interconnection patterns 243 corresponds to the V2 of the via that connects the M2 and M3 of the metallization layers of the semiconductor device.

Referring to FIG. 2F, a plurality of cut patterns 233-1 are placed. Each of the cut patterns 233-1 is configured to define a region where a metallization layer is undesired or a region of a metallization layer to be cut. In some embodiments, the location of the cut patterns 233-1 depends on a location of the respective (or closest) interconnection pattern 241. In some embodiments, a location of the edge 233e1 of the cut pattern 233-1 depends on the location of the respective (or closest) interconnection pattern 241 by the minimum distance, which is determined by design rules or design requirements. In some embodiments, a location of the edge 233e2 of the cut pattern 233-1 depends on the location of the respective (or closest) edge 233e1 by the minimum separation distance, which is determined by design rules or design requirements. The cut pattern 233-1 is located at a level which is the same as that of the M(i+1), such as the M1, of a metallization layer of the semiconductor device and overlaps the set 210b of the conductive patterns 210-1 to 210-10. For example, each of the cut patterns 233-1 overlaps the conductive pattern 210-3 (or 210-4, 210-5, or 210-6). A plurality of cut patterns 233-2 are placed. Each of the cut patterns 233-2 is configured to define a region where a metallization layer is undesired or a region of a metallization layer to be cut. In some embodiments, the location of the cut patterns 233-2 depends on a location of the respective (or closest) interconnection pattern 242. The cut pattern 233-2 is located at a level which is the same as that of the M(i+1), such as the M1, of a metallization layer of the semiconductor device and overlaps the set 210b of the conductive patterns 210-1 to 210-10. For example, each of the cut patterns 233-2 overlaps the conductive pattern 210-3 (or 210-4, 210-5, or 210-6). A plurality of cut patterns 234-1 are placed. Each of the cut patterns 234-1 is configured to define a region where a metallization layer is undesired or a region of a metallization layer to be cut. In some embodiments, the location of the cut patterns 234-1 depends on a location of the respective (or closest) interconnection pattern 242. The cut pattern 234-1 is located at a level which is the same as that of the M(i+2), such as the M2, of a metallization layer of the semiconductor device and overlaps the set 220b of the conductive patterns 220-1 to 220-10. For example, each of the cut patterns 234-1 overlaps the conductive pattern 220-6 (or 220-7). A plurality of cut patterns 234-2 are placed. Each of the cut patterns 234-2 is configured to define a region where a metallization layer is undesired or a region of a metallization layer to be cut. In some embodiments, the location of the cut patterns 234-2 depends on a location of the respective (or closest) interconnection pattern 243. The cut patterns 234-2 is located at a level which is the same as that of the M(i+2), such as the M2, of a metallization layer of the semiconductor device and overlaps the set 220b of the conductive patterns 220-1 to 220-10. For example, each of the cut patterns 234-2 overlaps the conductive pattern 220-6 (or 220-7).

Referring to FIG. 2G, the set 210b of the conductive patterns 210-1 to 210-10 is cut. The set 220b of the conductive patterns 220-1 and 220-10 is cut. As a result, an isolated pattern 250a is produced. The isolated pattern 250a includes the pin 201, the conductive patterns (or revised conductive patterns) 210-3 to 210-6, 220-6 and 220-7, as well as the pin 202. In some embodiments, the isolated pattern 250a corresponds to a dummy pattern of the semiconductor device, which is a non-functional conductive structure of the semiconductor device. In some embodiments, the isolated pattern 250a corresponds to a conductive structure that is electrically floating.

In a comparative layout design procedure, a post-dummy-fill technique is preformed, which forms a functional circuit first and a dummy pattern last. In the post-dummy-fill technique, much manual work is required to construct a multilayer structure. In the embodiments of the present disclosure, the dummy pattern fills first, which reduces the amount of manual work in comparison with the post-dummy-fill technique. Further, since the pattern of the dummy pattern (or an isolated pattern) and the space between the dummy pattern (or an isolated pattern) and the routed traces can be determined before routing, the electrical capacitance can be guaranteed and satisfies the design requirements.

FIG. 3A, FIG. 3B, FIG. 3C, FIG. 3D, FIG. 3E, FIG. 3F, FIG. 3G and FIG. 3H illustrate various stages in the manufacture of a layout 200b for a semiconductor device, in accordance with some embodiments of the present disclosure.

Referring to FIG. 3A, a pin 201 and a pin 203 are placed. In some embodiments, each of the pin 201 and/or pin 203 is a terminal of a layout. In some embodiments, the pin 203 corresponds to the M(i+m) of a metallization layer of the semiconductor device, where m is an integer and m≥2. In some embodiments, m is equal to 2. For example, the pin 201 corresponds to the M0, and the pin 203 corresponds to the M2 of the metallization layer of the semiconductor device.

Referring to FIG. 3B, 210-1, 210-2, 210-3, 210-4, 210-5, 210-6, 210-7, 210-8, 210-9, and 210-10 are generated. In some embodiments, each of the conductive patterns 210-1 to 210-10 corresponds to the M(i+1) of a metallization layer of the semiconductor device. In some embodiments, each of the conductive patterns 220-1 to 220-10 corresponds to the M(i+2) of a metallization layer of the semiconductor device. For example, each of the conductive patterns 220-1 to 220-10 corresponds to the M2 of the metallization layer of the semiconductor device. In some embodiments, the pin 203 is located at a level which is the same as that of the conductive patterns 220-1 to 220-10. Further, the pin 203 overlaps at least one of the conductive patterns 220-1 to 220-10. For example, the pin 203 overlaps the conductive pattern 220-6.

Referring to FIG. 3C, a plurality of cut patterns 235 are placed. Each of the cut patterns 235 is configured to define a region where a metallization layer is undesired or a region of a metallization layer to be cut so that the pin 203 can be separated from the conductive patterns 220-1 to 220-10. The cut patterns 235 are located at a level which is the same as that of the M(i+2), such as the M2, of a metallization layer of the semiconductor device and overlap at least one of the conductive patterns 220-1 to 220-10. For example, the cut patterns 235 overlap the conductive patterns 220-6.

Referring to FIG. 3D, the conductive pattern 220-6 is cut, and the pin 203 is separated from the conductive patterns 220-1 to 220-10. In some embodiments, a set 210c of the conductive patterns 210-1 to 210-10 is selected. In some embodiments, the set 210c is configured to determine a metallization layer(s) which is electrically connected to the pin 201 and on which the interconnection pattern(s) is placed. In some embodiments, the set 210c of the conductive patterns 210-1 to 210-10 overlaps the pin 201. For example, the conductive patterns 210-1 to 210-4 are selected. In some embodiments, a set 220c of the conductive patterns 220-1 to 220-10 is selected. In some embodiments, the set 220c is configured to determine a metallization layer(s) which is electrically connected to the pin 203 and on which the interconnection pattern(s) is placed. In some embodiments, the set 220c of the conductive patterns 220-1 to 220-10 and the pin 203 are aligned along the X-axis. For example, the conductive pattern 220-6 is selected.

Referring to FIG. 3E, a plurality of interconnection patterns 244 are placed. Each of the interconnection patterns 244 overlaps the set 210c of the conductive patterns 210-1 to 210-10 and the pin 201. For example, each of the interconnection patterns 244 overlaps the conductive pattern 210-1 (or 210-2, or pin 201-3, or 210-4) and the pin 201. Each of the interconnection patterns 244 corresponds to V(i) of a via of the semiconductor device. For example, each of the interconnection patterns 244 corresponds to the V0 of the via that connects the M0 and M1 of the metallization layers of the semiconductor device. A plurality of interconnection patterns 245 are placed. Each of the interconnection patterns 245 overlaps the set 210c of the conductive patterns 210-1 to 210-10 and the set 220c of the conductive patterns 220-1 to 220-10. For example, each of the interconnection patterns 245 overlaps the conductive pattern 210-1 (or 210-2, or, 210-3, or 210-4) and the conductive pattern 220-6. Each of the interconnection patterns 245 corresponds to V(i+1) of a via of the semiconductor device. For example, each of the interconnection patterns 245 corresponds to the V1 of the via that connects the M1 and M2 of the metallization layers of the semiconductor device.

Referring to FIG. 3F, the pin 203 is connected to the conductive patterns 220-6 by a connective pattern 220d. The connective pattern 220d is configured to connect the pin 203 and the set 220c of the conductive patterns 220-1 to 220-10. The connective pattern 220d corresponds to the M(i+2) of a metallization layer of the semiconductor device. For example, the connective pattern 220d corresponds to the M2 of the metallization layer of the semiconductor device.

Referring to FIG. 3G, a plurality of cut patterns 236-1 are placed. Each of the cut patterns 236-1 is configured to define a region where a metallization layer is undesired or a region of a metallization layer to be cut. In some embodiments, the location of the cut patterns 236-1 depends on a location of the respective (or closest) interconnection pattern 244. The cut pattern 236-1 is located at a level which is the same as that of the M(i+1), such as the M1, of a metallization layer of the semiconductor device and overlaps the set 210c of the conductive patterns 210-1 to 210-10. For example, each of the cut patterns 236-1 overlaps the conductive pattern 210-1 (or 210-2, 210-3, or 210-4). A plurality of cut patterns 236-2 are placed. Each of the cut patterns 236-2 is configured to define a region where a metallization layer is undesired or a region of a metallization layer to be cut. In some embodiments, the location of the cut patterns 236-2 depends on a location of the respective (or closest) interconnection pattern 245. The cut pattern 236-2 is located at a level which is the same as that of the M(i+1), such as the M1, of a metallization layer of the semiconductor device and overlaps the set 210c of the conductive patterns 210-1 to 210-10. For example, each of the cut patterns 236-2 overlaps the conductive pattern 210-1 (or 210-2, 210-3, or 210-4). At least one cut pattern 237 is placed. The cut pattern 237 is configured to define a region where a metallization layer is undesired or a region of a metallization layer to be cut. In some embodiments, the location of the cut pattern 237 depends on a location of the respective (or closest) interconnection pattern 245. The cut pattern 237 is located at a level which is the same as that of the M(i+2), such as the M2, of a metallization layer of the semiconductor device and overlaps the set 220c of the conductive patterns 220-1 to 220-10. For example, the cut pattern 237 overlaps the conductive patterns 220-6.

Referring to FIG. 3H, the set 210c of the conductive patterns 210-1 to 210-10 is cut. The set 220c of the conductive patterns 220-1 and 220-10 is cut. As a result, an isolated pattern 250b is produced. The isolated pattern 250b includes the pin 201, the conductive patterns (or revised patterns) 210-1 to 210-4, 220-6, and the pin 203. In some embodiments, the isolated pattern 250b corresponds to a dummy pattern of the semiconductor device, which is a non-functional conductive structure of the semiconductor device. In some embodiments, the isolated pattern 250b corresponds to a conductive structure that is electrically floating.

FIG. 4A and FIG. 4B illustrate various stages in the manufacture of a layout 200c for a semiconductor device, in accordance with some embodiments of the present disclosure.

Referring to FIG. 4A, an isolated pattern 250c may be generated. In some embodiments, the isolated pattern 250c may be the same as or similar to that of the isolated pattern 250b. It should be noted that conductive patterns, such as the conductive patterns 210-1 to 210-10 and 220-1 to 220-10, are omitted for brevity. In other embodiments, the isolated pattern 250c includes pins and conductive patterns including M(i), M(i+1), M(i+2), M(i+3), or more metallization layers of the semiconductor device. A circuit pattern 260 is generated. In some embodiments, the circuit pattern 260 is generated after the isolated pattern 250c is generated. In some embodiments, the circuit pattern 260 corresponds to a functional conductive structure of the semiconductor device. For example, the circuit pattern 260 corresponds to routed traces not left electrically floating but instead included in a signal path, e.g., a control signal path, a data signal path, a power path, or the like. For example, the circuit pattern 260 is electrically connected to a logical gate, e.g., a buffer, an inverter, a NAND, a NOR, or the like. In some embodiments, the circuit pattern 260 includes conductive patterns corresponding to M(i), M(i+1), M(i+2), M(i+3), and/or more metallization layers and vias located between said conductive patterns of the semiconductor device.

Referring to FIG. 4B, when the isolated pattern 250c is determined to be electrically connected to the circuit pattern 260, a connective pattern 270 is generated. The connective pattern 270 is configured to electrically connect one of the pins of the isolated pattern 250c and the circuit pattern 260. In some embodiments, the connective pattern 270 includes conductive patterns corresponding to M(i), M(i+1), M(i+2), M(i+3), and/or more metallization layers and vias located between said conductive patterns of the semiconductor device. Although not shown, it should be noted that the other one of the pins of the isolated pattern 250c can be electrically connected to another functional pattern or electrically connected to a power source.

In this embodiment, the isolated pattern 250c can be a dummy pattern or a pattern that is connected to a functional pattern, which depends on design and/or electrical requirements. Since the pattern of the isolated pattern and the space between the isolated pattern and the routed traces can be determined before routing, the electrical capacitance and/or other electrical properties can be guaranteed and satisfy the design requirements.

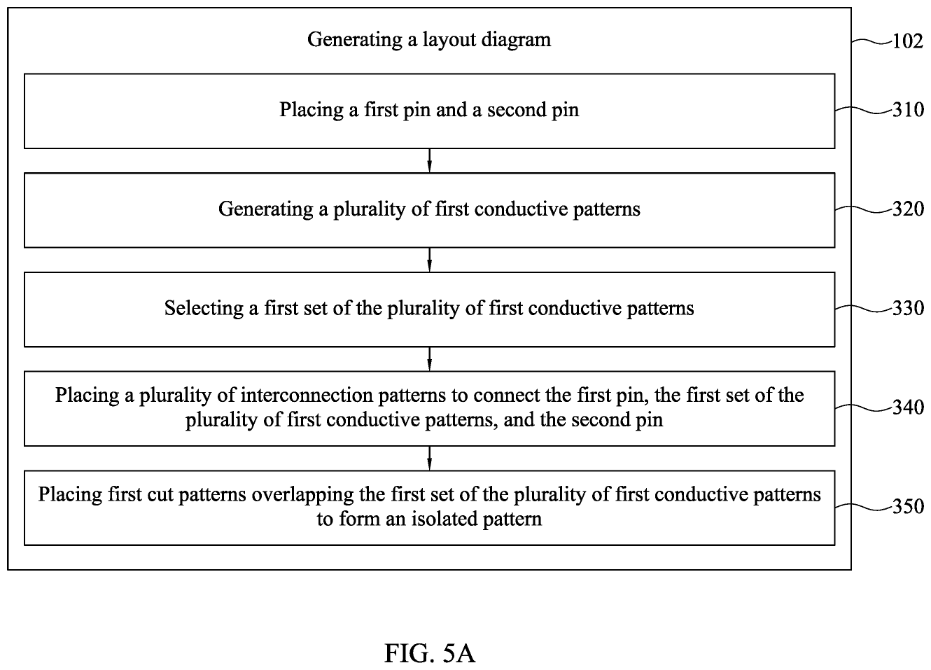

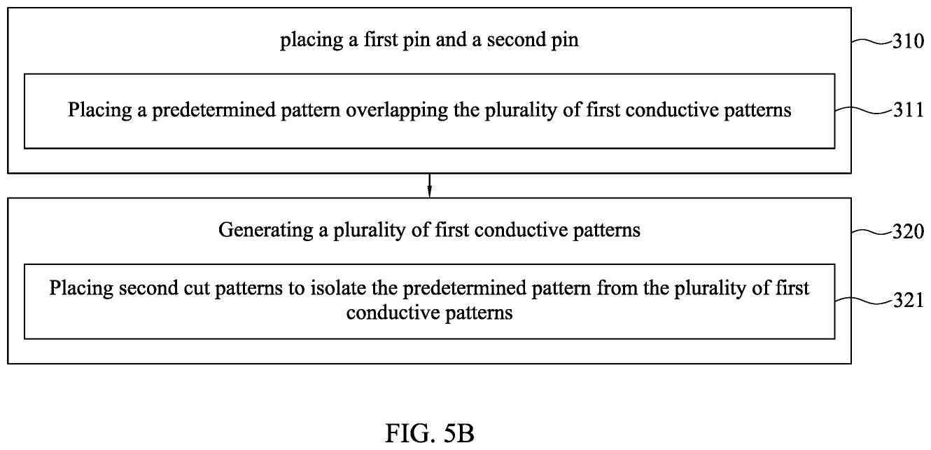

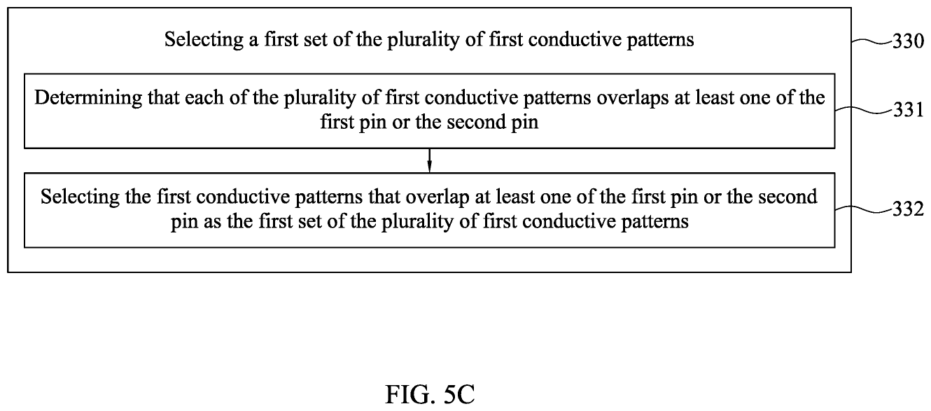

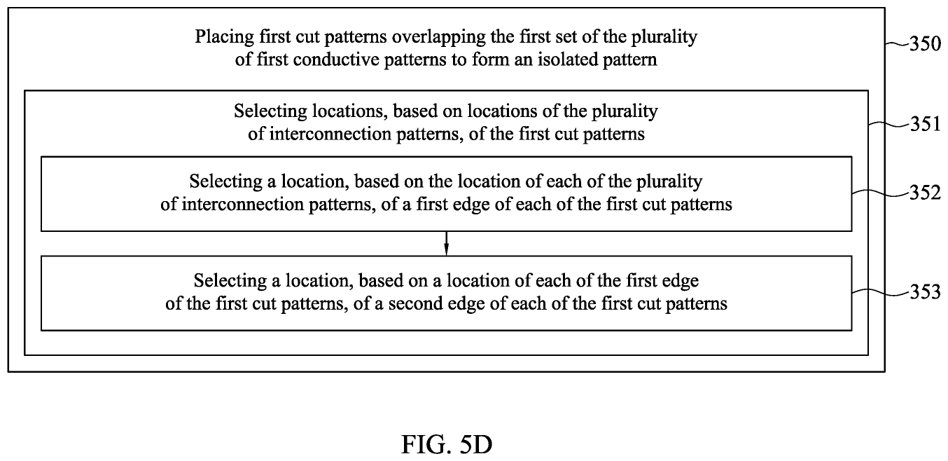

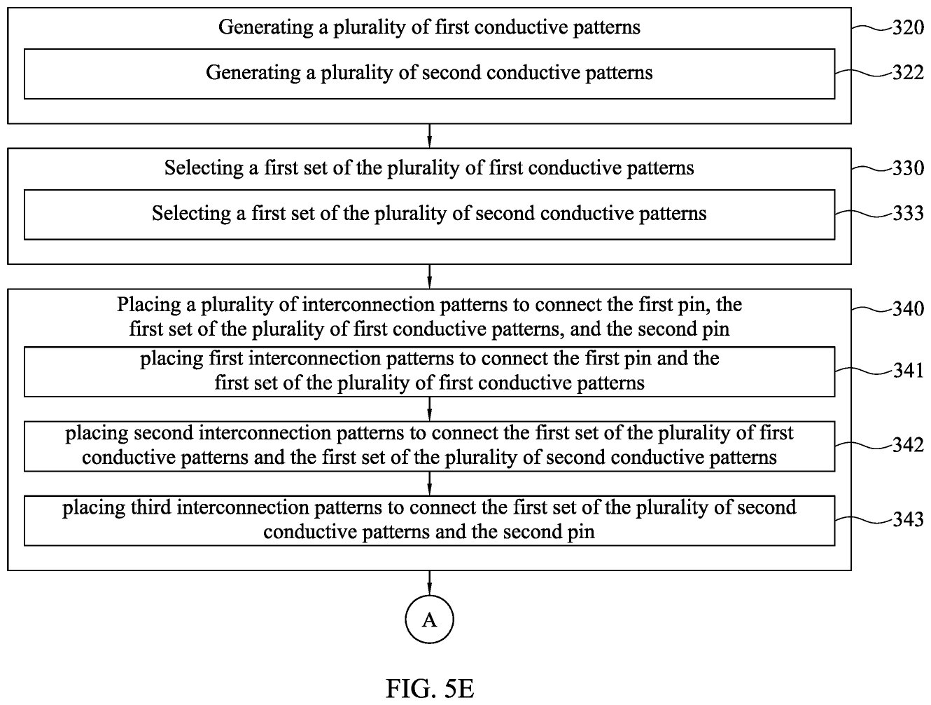

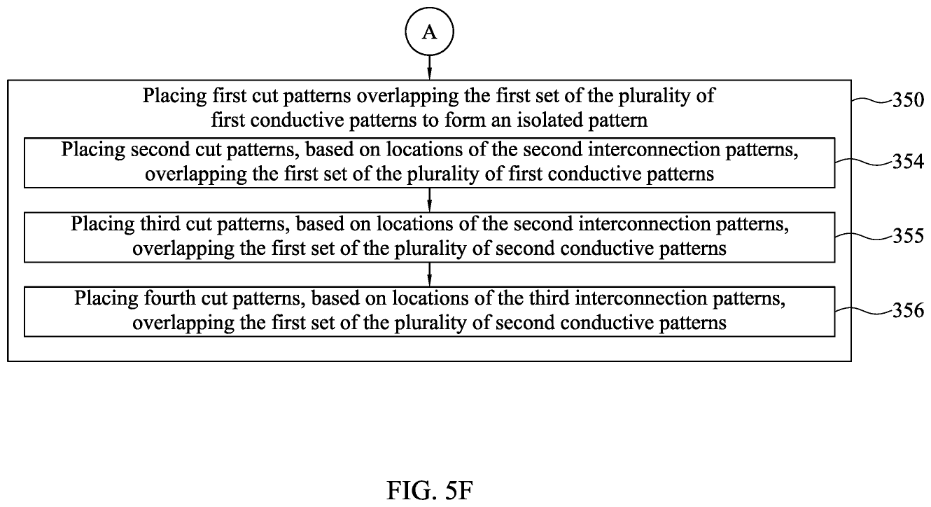

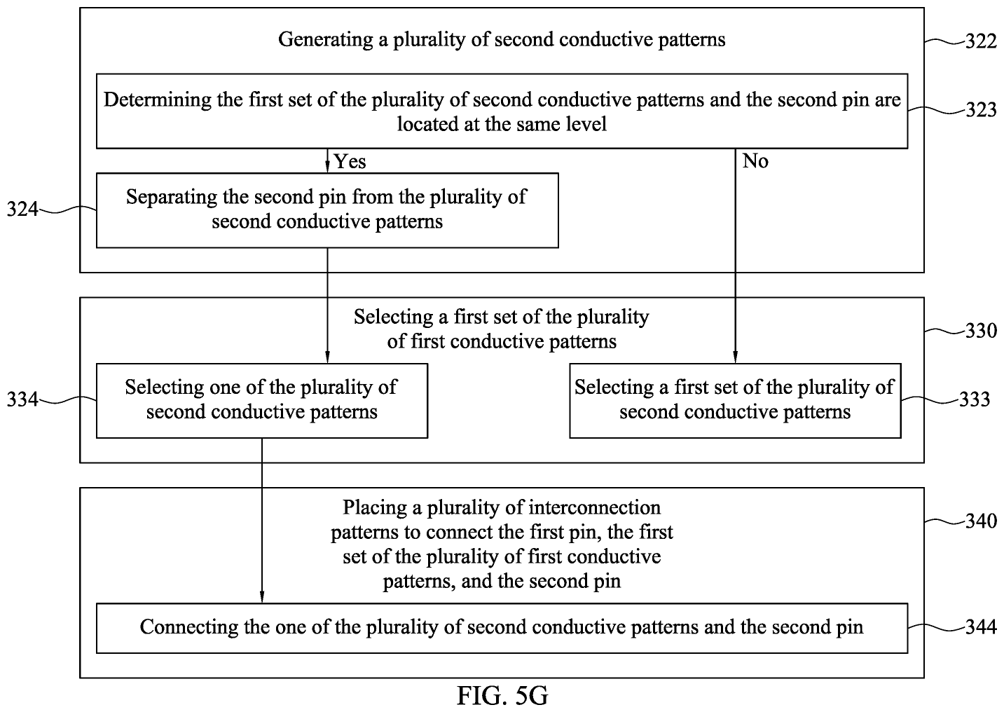

FIG. 5A to FIG. 5G are flowcharts of a method for manufacturing a layout of a semiconductor device according to various aspects of the present disclosure. More particularly, the method of FIG. 5A shows operation 102 of FIG. 1 in more detail, in accordance with one or more embodiments. For example, the method of FIG. 5A illustrates how to form an isolated pattern (or a dummy pattern) as shown in FIG. 2A to FIG. 2G and/or FIG. 3A to FIG. 3H. Each of FIG. 5B to FIG. 5G shows operation(s) of FIG. 5A in more detail.

Referring to FIG. 5A, operation 102 includes operations 310, 320, 330, 340, and 350.

Operation 310 includes placing a first pin and a second pin. Examples of the first pin and the second pin include pin 201 and pin 202 (or pin 203) in FIG. 2A and/or FIG. 3A.

Operation 320 includes generating a plurality of first conductive patterns. Examples of the first conductive patterns include the conductive patterns 210-1 to 210-10 and/or the conductive patterns 220-1 to 220-10 in FIG. 2B and/or FIG. 3B.

Operation 330 includes selecting a first set of the plurality of first conductive patterns. Examples of the first set of the plurality of first conductive patterns include the set 210b, 220b, 210c, and/or 220c in FIG. 2D and/or FIG. 3D.

Operation 340 includes placing a plurality of interconnection patterns to connect the first pin, the first set of the plurality of first conductive patterns, and the second pin. Examples of the interconnection patterns include the interconnection patterns 241 to 245 in FIG. 2E and/or FIG. 3E.

Operation 350 includes placing first cut patterns overlapping the first set of the plurality of first conductive patterns to form an isolated pattern. Examples of the first cut patterns include the cut patterns 233-1, 233-2, 234-1, 234-2, 236-1, 236-2, and/or 237 in FIG. 2F and/or FIG. 3G.

Referring to FIG. 5B, operation 310 includes operation 311. Operation 311 includes placing a predetermined pattern overlapping the plurality of first conductive patterns. Examples of the predetermined pattern include the predetermined patterns 212 in FIG. 2B. Operation 320 includes operation 321. Operation 321 includes placing second cut patterns to isolate the predetermined pattern from the plurality of first conductive patterns. Examples of the second cut patterns include the cut patterns 231 and 232 in FIG. 2C.

Referring to FIG. 5C, operation 330 includes operations 331 and 332. Operation 331 includes determining that each of the plurality of first conductive patterns overlaps at least one of the first pin or the second pin. When a first conductive pattern overlaps the first pin or the second pin, said first conductive pattern is selected; when a first conductive pattern does not overlap the first pin and the second pin, said first conductive pattern is not selected. Operation 332 includes selecting the first conductive patterns that overlap at least one of the first pin and the second pin as the first set of the plurality of first conductive patterns. Operations 331 and 332 correspond to the stage as shown in, for example, FIG. 2D.

Referring to FIG. 5D, operation 350 includes operation 351. Operation 351 includes selecting locations, based on locations of the plurality of interconnection patterns, of the first cut patterns. Operation 351 includes operations 352 and 353. Operation 352 includes selecting a location, based on the location of each of the plurality of interconnection patterns, of a first edge of each of the first cut patterns. Operation 353 includes selecting a location, based on the location of each of the first edge of the first cut patterns, of a second edge of each of the first cut patterns. Examples of the first edge and second edge of the first cut pattern include, for example, the edges 233e1 and 233e2 in FIG. 2F.

Referring to FIG. 5E, operation 320 includes operation 322. Operation 322 includes generating a plurality of second conductive patterns. In this embodiment, examples of the first conductive patterns and second conductive patterns include the conductive patterns 210-1 to 210-10 and the conductive patterns 220-1 to 220-10, respectively, in FIG. 2B.

Operation 330 includes operation 333. Operation 333 includes selecting a first set of the plurality of second conductive patterns. In this embodiment, examples of the first set of the first conductive patterns and the first set of the second conductive patterns include the sets 210b and 220b, respectively, in FIG. 2D.

Operation 340 includes operations 341, 342, and 343. Operation 341 includes placing first interconnection patterns to connect the first pin and the first set of the plurality of first conductive patterns. Operation 342 includes placing second interconnection patterns to connect the first set of the plurality of first conductive patterns and the first set of the plurality of second conductive pattern. Operation 343 includes placing third interconnection patterns to connect the first set of the plurality of second conductive patterns and the second pin. In this embodiment, examples of the first interconnection patterns, the second interconnection patterns, and the third interconnection patterns include the interconnection patterns 241, 242, and 243, respectively, in FIG. 2E.

Referring to FIG. 5F that follows operation 340 of FIG. 5E, operation 350 includes operations 354, 355, and 356. Operation 354 includes placing second cut patterns, based on locations of the second interconnection patterns, overlapping the first set of the plurality of first conductive patterns. Operation 355 includes placing third cut patterns, based on locations of the second interconnection patterns, overlapping the first set of the plurality of second conductive patterns. Operation 356 includes placing fourth cut patterns, based on locations of the third interconnection patterns, overlapping the first set of the plurality of second conductive patterns. In this embodiment, the first cut patterns, second cut patterns, third cut patterns, and fourth cut patterns include the cut patterns 233-1, 233-2, 234-1, and 234-2, respectively, in FIG. 2F.

Referring to FIG. 5G, operation 322 includes operation 323. Operation 323 includes determining that the first set of the plurality of second conductive patterns and the second pin are located at the same level. When the first set of the plurality of second conductive patterns and the second pin are located at the same level, operation 322 includes operation 324. Operation 324 includes separating the second pin from the plurality of second conductive patterns. Operation 330 includes operation 334 following operation 324. Operation 334 includes selecting one of the plurality of second conductive patterns. When the first set of the plurality of second conductive patterns and the second pin are not located at the same level, operation 323 is followed by operation 333. Operation 340 includes operation 344 following operation 334. Operation 344 includes connecting the one of the plurality of second conductive patterns and the second pin. Operations 323, 324, 334, and 344 involve stages as shown in FIG. 3B, FIG. 3C, FIG. 3D, and FIG. 3F.

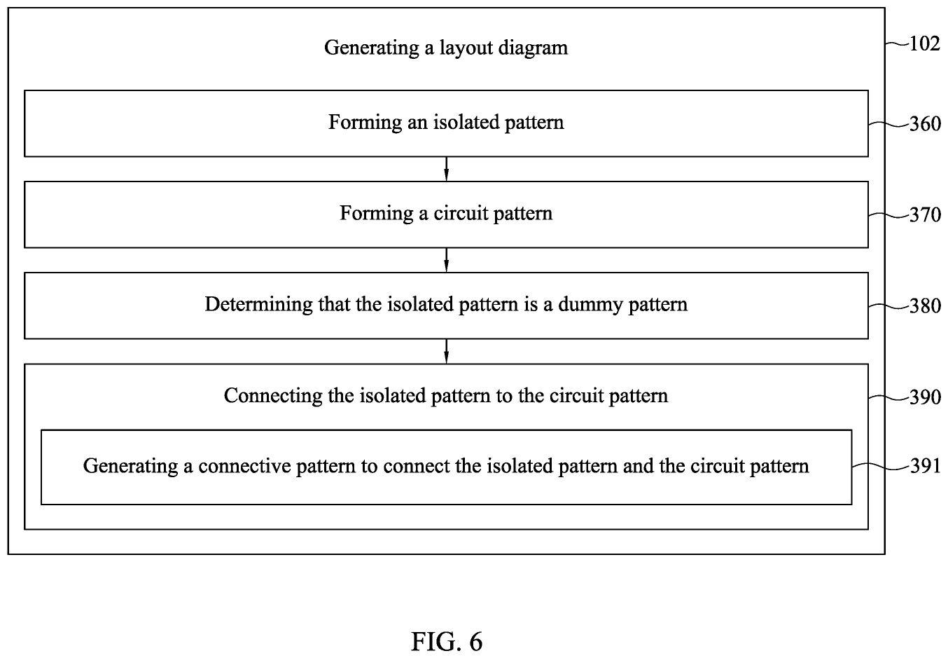

FIG. 6 is a flowchart of a method for manufacturing a layout of a semiconductor device according to various aspects of the present disclosure. More particularly, the method of FIG. 6 shows operation 102 of FIG. 1 in more detail, in accordance with one or more embodiments. For example, the method of FIG. 6 illustrates how to connect an isolated pattern to a circuit pattern as shown in FIG. 4A and FIG. 4B.

Operation 102 includes operations 360, 370, 380, and 390.

Operation 360 includes forming an isolated pattern. An example of the isolated pattern includes the isolated pattern 250c in FIG. 4A. In some embodiments, the isolated pattern can be produced by operations as described in FIG. 5A to FIG. 5G.

Operation 370 includes forming a circuit pattern. An example of the circuit pattern includes the circuit pattern 260 in FIG. 4A.

Operation 380 includes determining that the isolated pattern is a dummy pattern. When the isolated pattern is a dummy pattern, the isolated pattern keeps electrically floating. When the isolated pattern is not a dummy pattern, the operation 380 continues to operation 390.

Operation 390 includes connecting the isolated pattern to the circuit pattern. Operation 390 includes operation 391. Operation 391 includes generating a connective pattern to connect the isolated pattern and the circuit pattern. An example of the connective pattern includes the connective pattern 270 in FIG. 4B.

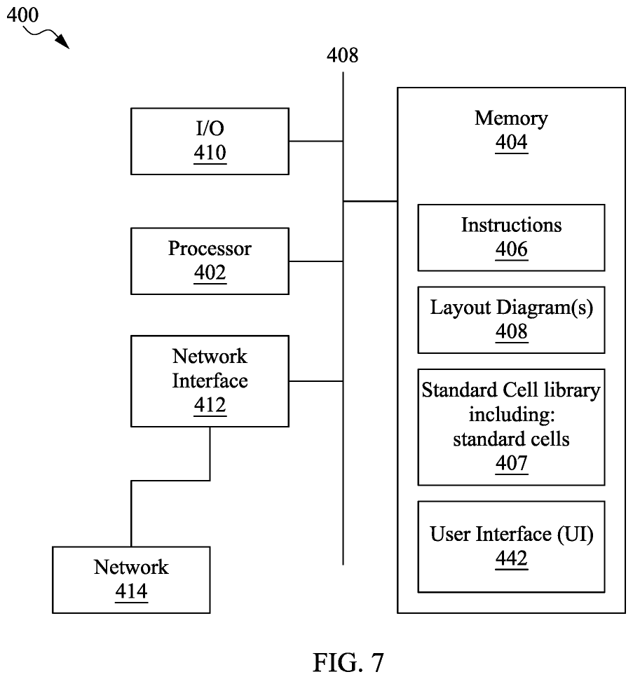

FIG. 7 is a block diagram of a system 400 of designing a semiconductor device, in accordance with some embodiments. The system 400 can include, for example, an electronic design automation (EDA) system.

In some embodiments, system 400 includes an automatic placement and routing (APR) system. Methods described herein of generating PG layout diagrams, in accordance with one or more embodiments, are implementable, for example, using the system 400, in accordance with some embodiments.

In some embodiments, system 400 is a general purpose computing device including a hardware processor 402 and a non-transitory, computer-readable storage medium 404. Storage medium 404, amongst other things, is encoded with, i.e., stores, computer program code 406, i.e., a set of executable instructions. Execution of instructions 406 by hardware processor 402 represents (at least in part) an EDA tool which implements a portion or all of a method according to an embodiment, e.g., the methods described herein in accordance with one or more embodiments (hereinafter, the noted processes and/or methods).

Processor 402 is electrically coupled to computer-readable storage medium 404 via a bus 408. Processor 402 is also electrically coupled to an I/O interface 410 by bus 408. A network interface 412 is also electrically connected to processor 402 via bus 408. Network interface 412 is connected to a network 414, so that processor 402 and computer-readable storage medium 404 are capable of connecting to external elements via network 414. Processor 402 is configured to execute computer program code 406 encoded in computer-readable storage medium 404 in order to cause system 400 to be usable for performing a portion or all of the noted processes and/or methods. In one or more embodiments, processor 402 is a central processing unit (CPU), a multi-processor, a distributed processing system, an application specific integrated circuit (ASIC), and/or a suitable processing unit.

In one or more embodiments, computer-readable storage medium 404 is an electronic, magnetic, optical, electromagnetic, infrared, and/or semiconductor system (or apparatus or device). For example, computer-readable storage medium 404 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 404 includes a compact disk-read only memory (CD-ROM), a compact disk-read/write (CD-R/W), and/or a digital video disc (DVD).

In one or more embodiments, storage medium 404 stores computer program code (instructions) 406 configured to cause system 400 (where such execution represents (at least in part) the EDA tool) to be usable for performing a portion or all of the noted processes and/or methods. In one or more embodiments, storage medium 404 also stores information which facilitates performing a portion or all of the noted processes and/or methods. In one or more embodiments, storage medium 404 stores library 407 of standard cells including such standard cells as disclosed herein and one or more layout diagrams 408 such as are disclosed herein.

System 400 includes I/O interface 410. I/O interface 410 is coupled to external circuitry. In one or more embodiments, I/O interface 410 includes a keyboard, keypad, mouse, trackball, trackpad, touchscreen, and/or cursor direction keys for communicating information and commands to processor 402.

System 400 also includes network interface 412 coupled to processor 402. Network interface 412 allows system 400 to communicate with network 414, to which one or more other computer systems are connected. Network interface 412 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 400.

System 400 is configured to receive information through I/O interface 410. The information received through I/O interface 410 includes one or more of instructions, data, design rules, libraries of standard cells, and/or other parameters for processing by processor 402. The information is transferred to processor 402 via bus 408. System 400 is configured to receive information related to a UI through I/O interface 410. The information is stored in computer-readable medium 404 as user interface (UI) 442.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods are implemented as a software application running on System 400. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

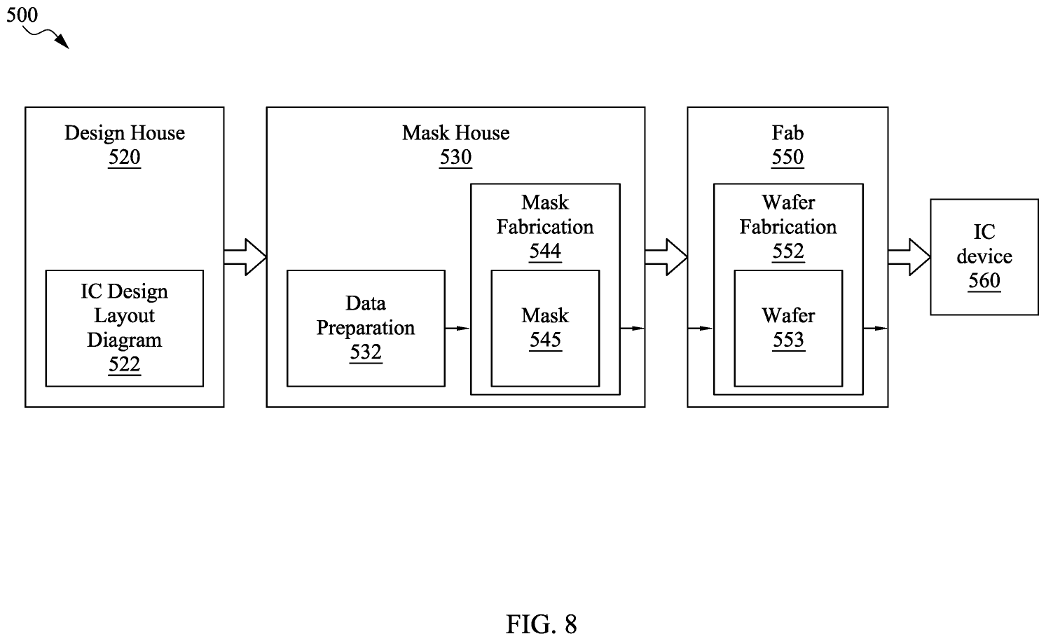

FIG. 8 is a block diagram of a semiconductor device manufacturing system 500, and a semiconductor device flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 500.

In FIG. 8, IC manufacturing system 500 includes entities, such as a design house 520, a mask house 530, and an IC manufacturer/fabricator (“fab”) 550, that interact with one another in the design, development, and manufacturing cycles and/or services related to manufacturing an IC device 560. The entities in system 500 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 520, mask house 530, and IC fab 550 is owned by a single larger company. In some embodiments, two or more of design house 520, mask house 530, and IC fab 550 coexist in a common facility and use common resources.

Design house (or design team) 520 generates an IC design layout diagram 522. IC design layout diagram 522 includes various geometrical patterns designed for an IC device 560. The geometrical patterns correspond to patterns of metal, oxide, or semiconductor layers that make up the various components of IC device 560 to be fabricated. The various layers combine to form various IC features. For example, a portion of IC design layout diagram 522 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 520 implements a proper design procedure to form IC design layout diagram 522. The design procedure includes one or more of logic design, physical design or place and route. IC design layout diagram 522 is presented in one or more data files having information of the geometrical patterns. For example, IC design layout diagram 522 can be expressed in a GDSII file format or DFII file format.

Mask house 530 includes data preparation 532 and mask fabrication 544. Mask house 530 uses IC design layout diagram 522 to manufacture one or more masks 545 to be used for fabricating the various layers of IC device 560 according to IC design layout diagram 522. Mask house 530 performs mask data preparation 532, where IC design layout diagram 522 is translated into a representative data file (“RDF”). Mask data preparation 532 provides the RDF to mask fabrication 544. Mask fabrication 544 includes a mask writer. A mask writer converts the RDF to an image on a substrate, such as a mask (reticle) 545 or a semiconductor wafer 553. The design layout diagram 522 is manipulated by mask data preparation 532 to comply with particular characteristics of the mask writer and/or requirements of IC fab 550. In FIG. 8, mask data preparation 532 and mask fabrication 544 are illustrated as separate elements. In some embodiments, mask data preparation 532 and mask fabrication 544 can be collectively referred to as mask data preparation.

In some embodiments, mask data preparation 532 includes optical proximity correction (OPC) which uses lithography enhancement techniques to compensate for image errors, such as those that can arise from diffraction, interference, other process effects and the like. OPC adjusts IC design layout diagram 522. In some embodiments, mask data preparation 532 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 532 includes a mask rule checker (MRC) that checks the IC design layout diagram 522 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 522 to compensate for limitations during mask fabrication 544, which may undo part of the modifications performed by OPC in order to meet mask creation rules.

In some embodiments, mask data preparation 532 includes lithography process checking (LPC) that simulates processing that will be implemented by IC fab 550 to fabricate IC device 560. LPC simulates this processing based on IC design layout diagram 522 to create a simulated manufactured device, such as IC device 560. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 522.

It should be understood that the foregoing description of mask data preparation 532 has been simplified for the purposes of clarity. In some embodiments, data preparation 532 includes additional features such as a logic operation (LOP) to modify the IC design layout diagram 522 according to manufacturing rules. Additionally, the processes applied to IC design layout diagram 522 during data preparation 532 may be executed in a variety of different orders.

After mask data preparation 532 and during mask fabrication 544, a mask 545 or a group of masks 545 are fabricated based on the modified IC design layout diagram 522. In some embodiments, mask fabrication 544 includes performing one or more lithographic exposures based on IC design layout diagram 522. In some embodiments, an electron-beam (e-beam) or a mechanism of multiple e-beams is used to form a pattern on a mask (photomask or reticle) 545 based on the modified IC design layout diagram 522. Mask 545 can be formed in various technologies. In some embodiments, mask 545 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 545 includes a transparent substrate (e.g., fused quartz) and an opaque material (e.g., chromium) coated in the opaque regions of the binary mask. In another example, mask 545 is formed using a phase shift technology. In a phase shift mask (PSM) version of mask 545, various features in the pattern formed on the phase shift mask are configured to have proper phase difference to enhance the resolution and imaging quality. In various examples, the phase shift mask can be attenuated PSM or alternating PSM. The masks generated by mask fabrication 544 are used in a variety of processes. For example, such a mask(s) can be used in an ion implantation process to form various doped regions in semiconductor wafer 553, in an etching process to form various etching regions in semiconductor wafer 553, and/or in other suitable processes.

IC fab 550 includes wafer fabrication 552. IC fab 550 is an IC fabricator that includes one or more manufacturing facilities for the fabrication of a variety of different IC products. In some embodiments, IC Fab 550 can be a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 550 uses mask(s) 545 fabricated by mask house 530 to fabricate IC device 560. Thus, IC fab 550 at least indirectly uses IC design layout diagram 522 to fabricate IC device 560. In some embodiments, semiconductor wafer 553 is fabricated by IC fab 550 using mask(s) 545 to form IC device 560. In some embodiments, the IC fabrication includes performing one or more lithographic exposures based at least indirectly on IC design layout diagram 522. Semiconductor wafer 553 includes a silicon substrate or other proper substrate having material layers formed thereon. Semiconductor wafer 553 further includes one or more of various doped regions, dielectric features, multilevel interconnects, and the like (formed at subsequent manufacturing steps).

Details regarding an integrated circuit (IC) manufacturing system (e.g., system 500 of FIG. 8), and an IC manufacturing flow associated therewith are found, e.g., in U.S. Pat. No. 9,256,709, granted Feb. 9, 2016, U.S. Pre-Grant Publication No. 20150278429, published Oct. 1, 2015, U.S. Pre-Grant Publication No. 20140040838, published Feb. 6, 2014, and U.S. Pat. No. 7,260,442, granted Aug. 21, 2007, the entireties of each of which are hereby incorporated by reference.

Some embodiments of the present disclosure provide a method of arranging patterns of a semiconductor device. The method includes: placing a first pin and a second pin, wherein the first pin corresponds to a first metallization layer located at a first level of the semiconductor device, and the second pin corresponds to a second metallization layer located at a second level higher than the first level of the semiconductor device; generating a plurality of first conductive patterns, wherein each of the plurality of first conductive patterns corresponds to a third metallization layer located at a third level between the first level and the second level of the semiconductor device; selecting a first set of the plurality of first conductive patterns; placing a plurality of interconnection patterns to connect the first pin, the first set of the plurality of first conductive patterns, and the second pin, wherein the plurality of interconnection patterns corresponds to vias between the first metallization layer and the third metallization layer as well as between the second metallization layer and the third metallization layer; and placing cut patterns overlapping the first set of the plurality of first conductive patterns to form an isolated pattern comprising the first pin, the first set of the plurality of first conductive patterns, and the second pin.

Some embodiments of the present disclosure provide a system for arranging patterns of a semiconductor device. The system includes at least one processing unit and at least one memory including computer program code for one or more programs. The at least one memory, the computer program code and the at least one processing unit are configured to cause the system to perform: placing a first pin and a second pin, wherein the first pin corresponds to a first metallization layer located at a first level of the semiconductor device, and the second pin corresponds to a second metallization layer located at a second level higher than the first level of the semiconductor device; generating a plurality of first conductive patterns, wherein each of the plurality of first conductive patterns corresponds to a third metallization layer located at a third level between the first level and the second level of the semiconductor device; selecting a first set of the plurality of first conductive patterns; placing a plurality of interconnection patterns to connect the first pin, the first set of the plurality of first conductive patterns, and the second pin, wherein the plurality of interconnection patterns corresponds to vias between the first metallization layer and the third metallization layer as well as between the second metallization layer and the third metallization layer; and placing first cut patterns overlapping the first set of the plurality of first conductive patterns to form an isolated pattern comprising the first pin, the first set of the plurality of first conductive patterns, and the second pin.

Some embodiments of the present disclosure provide a method of arranging patterns of a semiconductor device. The method includes: placing a first pin and a second pin, wherein the first pin corresponds to a first metallization layer located at a first level of the semiconductor device, and the second pin corresponds to a second metallization layer located at a second level higher than the first level of the semiconductor device; generating a plurality of first conductive patterns and a plurality of second conductive patterns, wherein each of the plurality of first conductive patterns corresponds to a third metallization layer located at a third level between the first level and the second level of the semiconductor device, and each of the plurality of second conductive patterns corresponds to a fourth metallization layer located at a fourth level between the second level and the third level of the semiconductor device; selecting a first set of the plurality of first conductive patterns and a first set of the plurality of second conductive patterns; connecting the first pin, the first set of the plurality of first conductive patterns, the first set of the plurality of second conductive patterns, and the second pin; and cutting the first set of the plurality of first conductive patterns and the first set of the plurality of second conductive patterns to form an isolated pattern comprising the first pin, the first set of the plurality of first conductive patterns, the first set of the plurality of second conductive patterns, and the second pin.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of arranging patterns of a semiconductor device, the method comprising:
placing a first pin and a second pin, wherein the first pin corresponds to a first metallization layer located at a first level of the semiconductor device, and the second pin corresponds to a second metallization layer located at a second level higher than the first level of the semiconductor device;
generating a plurality of first conductive patterns, wherein each of the plurality of first conductive patterns corresponds to a third metallization layer located at a third level between the first level and the second level of the semiconductor device;
selecting a first set of the plurality of first conductive patterns;
placing a plurality of interconnection patterns to connect the first pin, the first set of the plurality of first conductive patterns, and the second pin, wherein the plurality of interconnection patterns corresponds to vias between the first metallization layer and the third metallization layer as well as between the second metallization layer and the third metallization layer; and
placing cut patterns overlapping the first set of the plurality of first conductive patterns to form an isolated pattern comprising the first pin, the first set of the plurality of first conductive patterns, and the second pin.

2. The method of claim 1, wherein placing the cut patterns overlapping the first set of the plurality of first conductive patterns comprises:
selecting locations, based on locations of the plurality of interconnection patterns, of the cut patterns.

3. The method of claim 1, further comprising:
generating a plurality of second conductive patterns, wherein each of the plurality of second conductive patterns corresponds to the second metallization layer of the semiconductor device; and
separating the second pin from the plurality of second conductive patterns.

4. The method of claim 3, further comprising:
selecting one of the plurality of second conductive patterns, wherein a set of the plurality of interconnection patterns overlaps the one of the plurality of second conductive patterns and the set of the plurality of first conductive patterns; and
connecting the one of the plurality of second conductive patterns and the second pin.

5. The method of claim 1, further comprising:
placing a predetermined pattern overlapping the plurality of first conductive patterns, wherein the predetermined pattern corresponds to a set of routed conductive layers at the third level of the semiconductor device; and
placing second cut patterns to isolate the predetermined pattern from the plurality of first conductive patterns.

6. The method of claim 1, wherein the first set of the plurality of first conductive patterns at least overlap either the first pin or the second pin.

7. The method of claim 1, wherein the isolated pattern corresponds to a non-functional conductive structure of the semiconductor device.

8. A system for arranging patterns of a semiconductor device, comprising:
at least one processing unit; and
at least one memory including computer program code for one or more programs;
wherein the at least one memory, the computer program code and the at least one processing unit are configured to cause the system to perform:
placing a first pin and a second pin, wherein the first pin corresponds to a first metallization layer located at a first level of the semiconductor device, and the second pin corresponds to a second metallization layer located at a second level higher than the first level of the semiconductor device;
generating a plurality of first conductive patterns, wherein each of the plurality of first conductive patterns corresponds to a third metallization layer located at a third level between the first level and the second level of the semiconductor device;
selecting a first set of the plurality of first conductive patterns;
placing a plurality of interconnection patterns to connect the first pin, the first set of the plurality of first conductive patterns, and the second pin, wherein the plurality of interconnection patterns corresponds to vias between the first metallization layer and the third metallization layer as well as between the second metallization layer and the third metallization layer; and
placing first cut patterns overlapping the first set of the plurality of first conductive patterns to form an isolated pattern comprising the first pin, the first set of the plurality of first conductive patterns, and the second pin.

9. The system of claim 8, wherein the at least one memory, the computer program code and the at least one processing unit are further configured to cause the system to select locations, based on locations of the plurality of interconnection patterns, of the first cut patterns.

10. The system of claim 8, wherein the at least one memory, the computer program code and the at least one processing unit are further configured to cause the system to generate a plurality of second conductive patterns, wherein each of the plurality of second conductive patterns corresponds to the second metallization layer of the semiconductor device and to separate the second pin from the plurality of second conductive patterns.

11. The system of claim 10, wherein the at least one memory, the computer program code and the at least one processing unit are further configured to cause the system to select one of the plurality of second conductive patterns and to connect the one of the plurality of second conductive patterns and the second pin.

12. The system of claim 8, wherein the at least one memory, the computer program code and the at least one processing unit are further configured to cause the system to place a predetermined pattern overlapping the plurality of first conductive patterns and to place second cut patterns to isolate the predetermined pattern from the plurality of first conductive patterns, wherein the predetermined pattern corresponds to a set of routed conductive layers at the third level of the semiconductor device.

13. The system of claim 8, wherein the isolated pattern corresponds to a non-functional conductive structure of the semiconductor device.

14. A method of arranging patterns of a semiconductor device, the method comprising:
placing a first pin and a second pin, wherein the first pin corresponds to a first metallization layer located at a first level of the semiconductor device, and the second pin corresponds to a second metallization layer located at a second level higher than the first level of the semiconductor device;
generating a plurality of first conductive patterns and a plurality of second conductive patterns, wherein each of the plurality of first conductive patterns corresponds to a third metallization layer located at a third level between the first level and the second level of the semiconductor device, and each of the plurality of second conductive patterns corresponds to a fourth metallization layer located at a fourth level between the second level and the third level of the semiconductor device;
selecting a first set of the plurality of first conductive patterns and a first set of the plurality of second conductive patterns;
connecting the first pin, the first set of the plurality of first conductive patterns, the first set of the plurality of second conductive patterns, and the second pin; and
cutting the first set of the plurality of first conductive patterns and the first set of the plurality of second conductive patterns to form an isolated pattern comprising the first pin, the first set of the plurality of first conductive patterns, the first set of the plurality of second conductive patterns, and the second pin.

15. The method of claim 14, wherein connecting the first pin, the first set of the plurality of first conductive patterns, the first set of the plurality of second conductive patterns, and the second pin comprises:
placing first interconnection patterns to connect the first pin and the first set of the plurality of first conductive patterns, wherein each of the first interconnection patterns corresponds to a first via between the first metallization layer and the third metallization layer; and
placing second interconnection patterns to connect the first set of the plurality of first conductive patterns and the first set of the plurality of second conductive patterns, wherein each of the second interconnection patterns corresponds to a second via between the third metallization layer and the fourth metallization layer; and
placing third interconnection patterns to connect the first set of the plurality of second conductive patterns and the second pin, wherein each of the third interconnection patterns corresponds to a third via between the second metallization layer and the fourth metallization layer.

16. The method of claim 14, further comprising:
placing a predetermined pattern overlapping the plurality of first conductive patterns or overlapping the plurality of second conductive patterns, wherein the predetermined pattern corresponds to a set of routed conductive layers at the third level or at the fourth level of the semiconductor device; and
cutting a second set of the plurality of first conductive patterns or a second set of the plurality of second conductive patterns to isolate the predetermined pattern.

17. The method of claim 14, wherein the isolated pattern corresponds to a non-functional conductive structure of the semiconductor device.

18. The method of claim 14, wherein cutting the first set of the plurality of first conductive patterns comprises:
placing first interconnection patterns to connect the first pin and the first set of the plurality of first conductive patterns, wherein each of the first interconnection patterns corresponds to a first via between the first metallization layer and the third metallization layer, and wherein cutting the first set of the plurality of first conductive patterns comprises:
placing first cut patterns, based on locations of the first interconnection patterns, overlapping the first set of the plurality of first conductive patterns.

19. The method of claim 18, wherein cutting the first set of the plurality of first conductive patterns further comprises:
placing second interconnection patterns to connect the first set of the plurality of first conductive patterns and the first set of the plurality of second conductive patterns, wherein each of the second interconnection patterns corresponds to a second via between the third metallization layer and the fourth metallization layer;
placing second cut patterns, based on locations of the second interconnection patterns, overlapping the first set of the plurality of first conductive patterns.

20. The method of claim 14, further comprising:
connecting the isolated pattern to a circuit pattern, wherein the circuit pattern corresponds to a functional conductive structure of the semiconductor device.
